(19) United States
(12) Patent Application Publication
(10) Pub. No.: US 2024/0359992 A1
(43) Pub. Date: Oct. 31, 2024

(54) TREATMENT METHOD

(71) Applicants: KABUSHIKI KAISHA TOSHIBA, Tokyo (JP); Kioxia Corporation, Tokyo (JP); TOHOKU UNIVERSITY, Sendai-shi (JP)

(72) Inventors: Kenya UCHIDA, Yokohama (JP); Hiroyuki FUKUI, Yokkaichi (JP); Takeaki IWAMOTO, Sendai-shi (JP)

(73) Assignees: KABUSHIKI KAISHA TOSHIBA, Tokyo (JP); Kioxia Corporation, Tokyo (JP); TOHOKU UNIVERSITY, Sendai-shi (JP)

(21) Appl. No.: 18/769,829

(22) Filed: Jul. 11, 2024

Related U.S. Application Data
(63) Continuation of application No. PCT/JP2023/001202, filed on Jan. 17, 2023.

(30) Foreign Application Priority Data
Jan. 18, 2022 (JP) 2022-005848

(51) Int. Cl. C01B 33/107

(52) U.S. Cl. CPC C01B 33/1071

(57) ABSTRACT

According to one embodiment, a treatment method for treating a mixture containing one or both of halosilanes and hydrolysates of the halosilanes is provided. The method includes bringing the mixture into contact with a treatment liquid. The treatment liquid has a pH of 8 to 14. The treatment liquid has a mass corresponding to 100 times or more a mass of the mixture.

### CROSS-REFERENCE TO RELATED APPLICATION

This application is a Continuation Application of PCT Application No. PCT/JP2023/001202, filed Jan. 17, 2023 and based upon and claiming the benefit of priority from Japanese Patent Application No. 2022-005848, filed Jan. 18, 2022, the entire contents of all of which are incorporated herein by reference.

### FIELD

Embodiments described herein relate generally to a treatment method.

### BACKGROUND

Semiconductor silicon substrates are widely used as materials for forming various electronic circuits. When forming a semiconductor silicon substrate and when forming a film or an ingot containing a silicon-containing substance, a silicon-containing substance forming apparatus, such as an epitaxial growth apparatus and a chemical vapor deposition apparatus, is used.

The epitaxial growth apparatus includes a reaction chamber, and a supply pipe and a discharge pipe connected to the reaction chamber. A material gas is supplied to the reaction chamber through the supply pipe. An exhaust gas is then discharged from the reaction chamber through the discharge pipe. In a case of using the epitaxial growth apparatus, a substrate is placed in a reaction chamber which is decompressed under an inert atmosphere. Then, the material gas introduced into the reaction chamber and the heated substrate are reacted with each other, whereby a film including a silicon-containing substance is formed on the substrate. As the material gas, for example, a mixed gas in which a compound containing silicon and chlorine is mixed in hydrogen gas is used. The material gas reacted with the substrate in the reaction chamber is discharged as the exhaust gas to the outside of the apparatus through the discharge pipe. The exhaust gas may contain components in the material gas, for example, a compound containing silicon and chlorine, or hydrogen gas.

Here, the temperature in the reaction chamber is significantly higher than that in the discharge pipe. Therefore, the compound including silicon and chlorine contained in the exhaust gas discharged into the discharge pipe may be cooled inside the discharge pipe and precipitated as a byproduct. The byproduct may include highly viscous liquid and solid substances, which are also referred to as oily silanes. The byproduct may also include substances secondarily produced by the deterioration of the oily silane in the air or water. It is required to render such a byproduct harmless in a safe manner.

### BRIEF DESCRIPTION OF THE DRAWING(S)

FIG. 1 is a schematic diagram showing an example of an epitaxial growth apparatus as an apparatus in which a byproduct to be treated is generated.

FIG. 2 is a schematic diagram showing a treatment apparatus for use in a method according to an embodiment.

FIG. 3 is a block diagram showing temperature control in the treatment apparatus shown in FIG. 2.

FIG. 4 is a flowchart showing a first example of a treatment method according to the embodiment.

FIG. 5 is a flowchart showing a second example of the treatment method according to the embodiment.

FIG. 6 is a flowchart showing a third example of the treatment method according to the embodiment.

FIG. 7 is a flowchart showing a fourth example of the treatment method according to the embodiment.

FIG. 8 is a flowchart showing a fifth example of the treatment method according to the embodiment.

### DETAILED DESCRIPTION

First, halosilanes to be treated will be described. The halosilanes include, for example, halosilanes having a chain structure and halosilanes having a cyclic structure. The halosilanes having a cyclic structure may be represented by any one of the following structural formulae (a) to (d). In the structural formulae (a) to (d), X is at least one halogen element selected from the group consisting of F, Cl, Br and I.

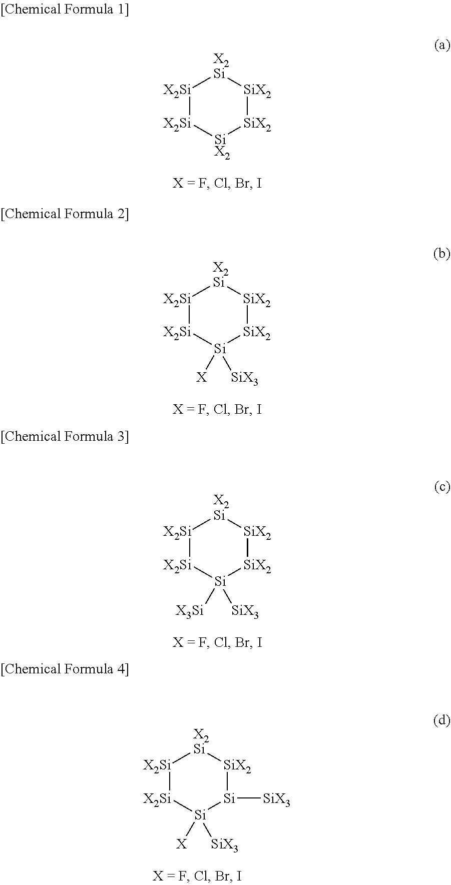

In the example of (d), a silyl group is bonded to Si atoms at positions 1 and 2 of a 6-membered ring structure, but the embodiment is not limited to this example. Examples include a 6-membered ring structure having silyl groups bonded to Si atoms at positions 1 and 3, and a 6-membered ring structure having silyl groups bonded to Si atoms at positions 1 and 4.

The halosilanes having a cyclic structure may have a 4-membered ring structure, a 5-membered ring structure, a 6-membered ring structure other than the structures represented by formulae (a) to (d), a 7-membered ring structure, an 8-membered ring structure, a multi-membered ring structure, or the like, as represented by the following structural formulae (1) to (21). In the following structural formulae (1) to (21), X is at least one halogen element selected from the group consisting of F, Cl, Br, and I. The following structural formulae (1-1) to (21-1) represent chlorosilanes represented by the structural formulae (1) to (21), respectively, in which the element X is chlorine.

The halosilanes having a cyclic structure applicable to the treatment method of the embodiment are not limited to those represented by the structural formulae (a) to (d), the structural formulae (1) to (21), and the structural formulae (1-1) to (21-1). The treatment method of the embodiment is also applicable to isomers including structural isomers of the compounds represented by these structural formulae. For example, the position of the silyl group of a 5-membered ring compound is not limited to the Si atoms at positions 1 and 2 exemplified in the structural formula (3), and may be the Si atoms at positions 1 and 3.

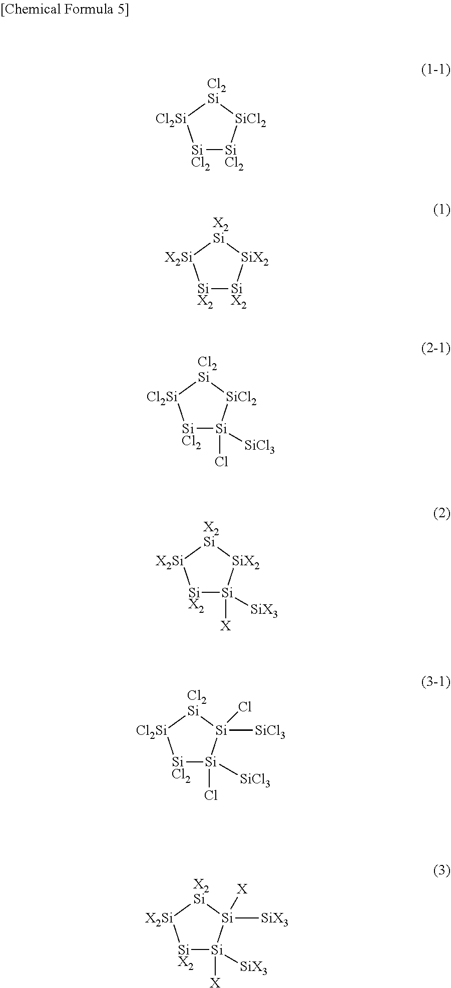

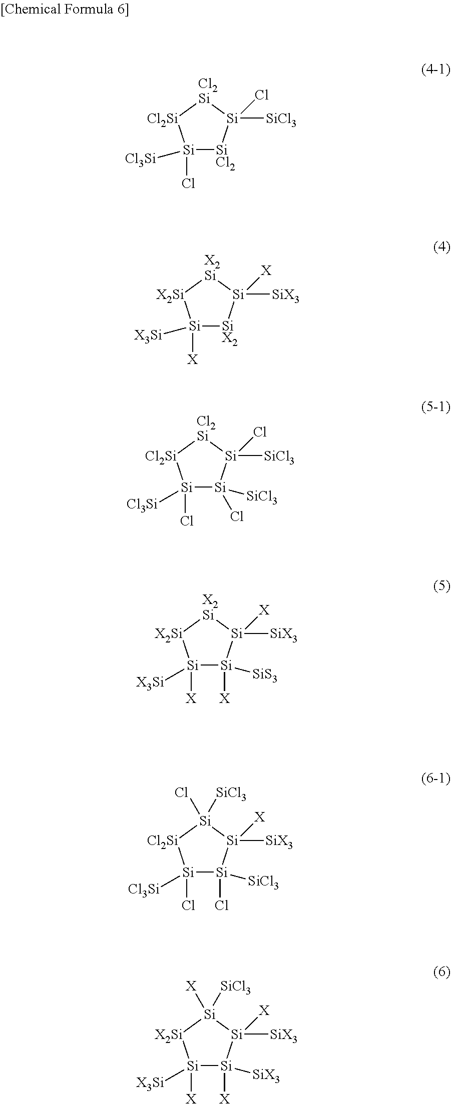

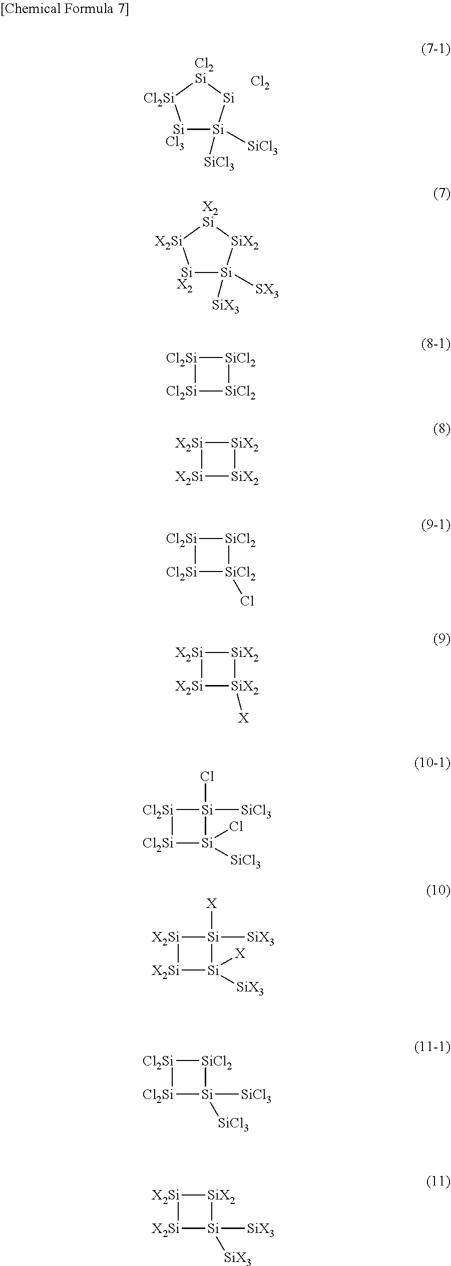

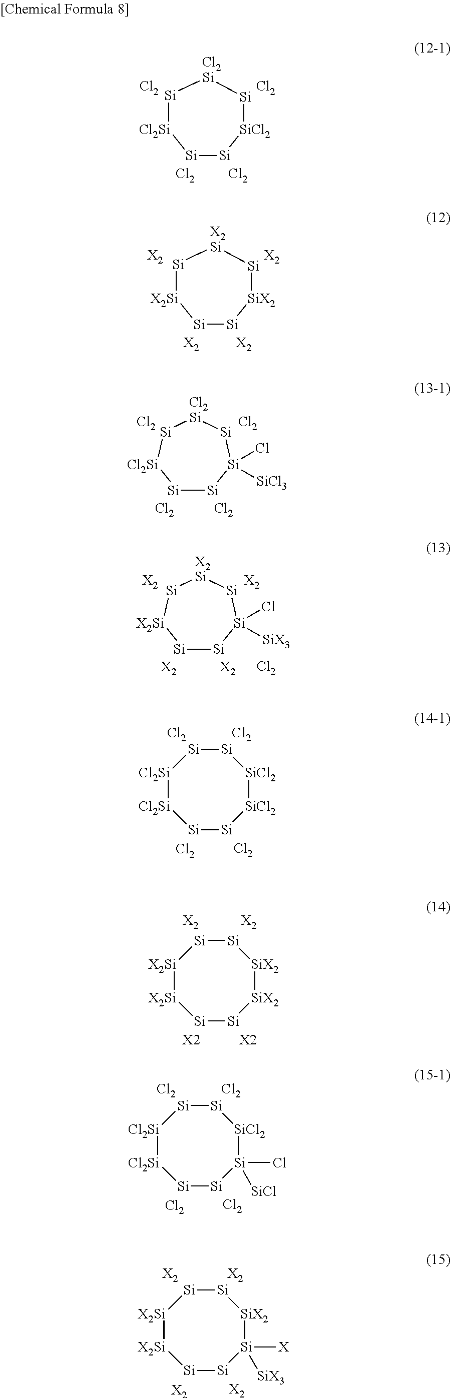

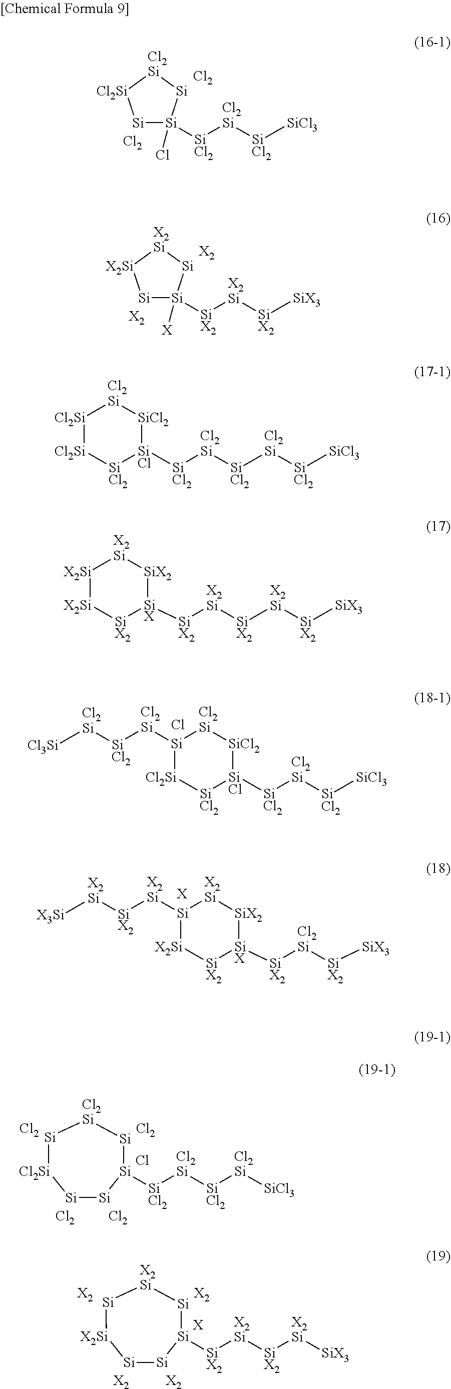

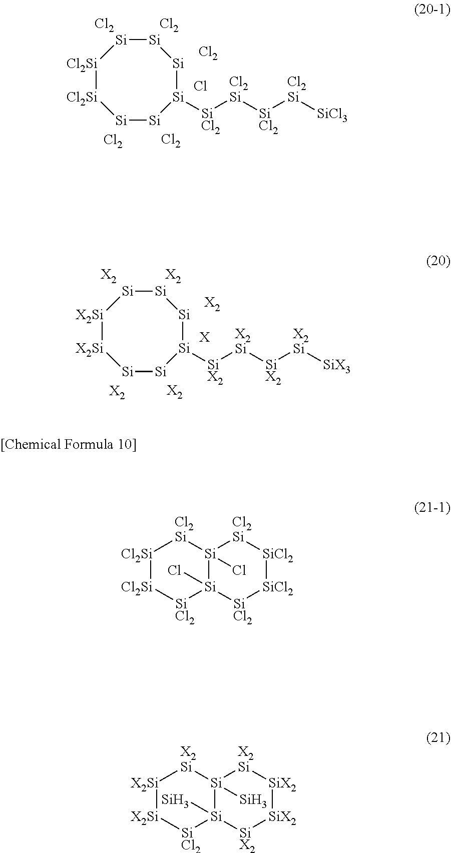

The halosilanes having a cyclic structure contained in the mixture may be homocyclic compounds having a silicon ring consisting of silicon as represented by the above structural formulae (1) to (21), and may also be inorganic cyclic compounds free from carbon as represented by the above structural formulae (1) to (21). The mixture may include a heterocyclic compound made of silicon and oxygen.

The halosilanes having a cyclic structure represented by the above structural formulae are thermodynamically stable. However, the halosilanes having the cyclic structure have a Si—Si bond and a Si—X bond (X is at least one halogen element selected from the group consisting of F, Cl, Br and I). These bonds display high reactivity to water. Therefore, the halosilanes having the cyclic structure are considered to rapidly react with water under air atmosphere. Such halosilanes are considered to further react with water to produce explosive substances. The explosive substances are considered to be, for example, silyl ethers, siloxanes, silanols, or mixtures thereof.

The halosilanes having a chain structure are represented by, for example, the following structural formulae (22) and (23). In the following structural formula (22), N is a positive integer; for example, an integer of 0 to 15. In the following structural formulae (22) and (23), X is at least one halogen element selected from the group consisting of F, Cl, Br, and I. The following structural formulae (22-1) and (23-1) respectively represent chlorosilanes represented by the structural formulae (22) and (23), in which the element X is chlorine.

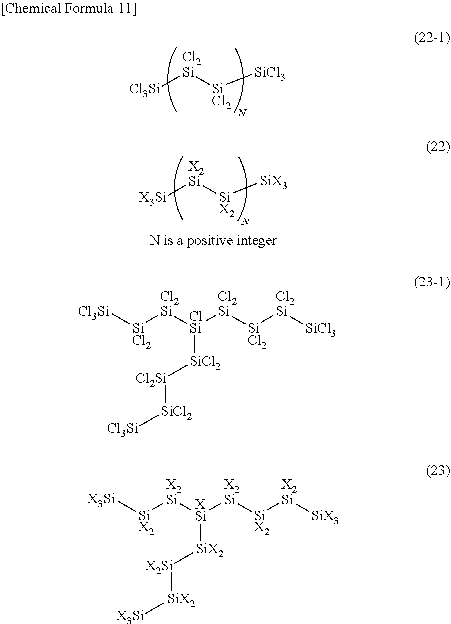

The halosilanes having a chain structure may be a linear compound having no branch as represented by the structural formula (22). Alternatively, the halosilanes having a chain structure may be a chain compound having a branch as represented by the structural formula (23). The fact that the mixture contains halosilanes having a chain structure can be presumed by mass spectrometry.

The fact that the mixture contains cyclic chlorosilanes can be presumed by the following method.

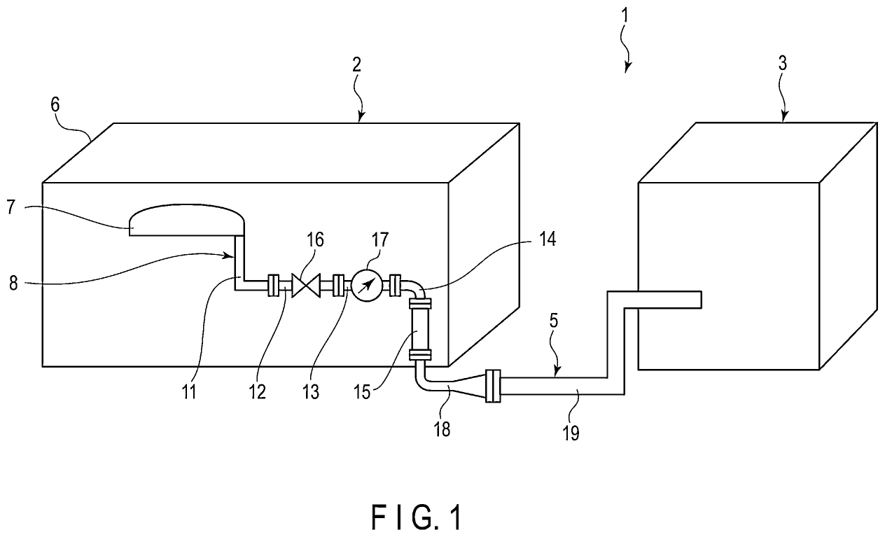

First, the silicon-containing substance forming apparatus is disassembled to remove the pipe to which the byproduct adheres. For example, like a pipe 14 shown in FIG. 1, which will be described later, a curved pipe located downstream of a pressure control valve 17 in an exhaust gas flow path is removed. Then, both ends of the removed pipe are closed. This operation is performed under inert atmosphere such as nitrogen (N₂) gas.

Next, the removed pipe is transferred into a glove box purged with an inert gas such as nitrogen gas. Subsequently, the byproduct is collected from the pipe, and analysis samples for use in nuclear magnetic resonance (NMR) spectroscopy and mass spectrometry (MS), respectively, are prepared. The atmosphere in the glove box is preferably an argon atmosphere with a moisture concentration of 1 ppm or less and an oxygen concentration of 10 ppm or less. As the glove box, for example, VAC101965OMNI-LAB STCH-A manufactured by VAC, Inc. is used. In bringing the analysis samples to their respective analyzers, each of the samples is placed in, for example, a container made of resin, which subsequently, in the state of being placed in a sealed container, is transferred from the glove box to the analyzer. In preparing each analysis sample, caution is taken not to bring the sample into contact with oxygen and water. At times when each analysis sample must unavoidably be exposed to air, such as when being placed in the analyzer, handling should be quickly executed.

Next, the byproduct is analyzed by a nuclear magnetic resonance (NMR) method. As an analysis sample, for example, a mixture having 0.2 g of the byproduct mixed with 2 mL of dehydrated heavy toluene (manufactured by Kanto Chemical Co., Inc.: Product No. 21744-1A) and then left alone for 4 hours is used. Next, this mixture is dispensed into a sample tube with a J. YOUNG valve (S-5-600-JY-8) manufactured by HARUNA Inc. Then, the NMR sample tube is set in an NMR spectrometer, and a ²⁹Si NMR spectrum is measured. As the NMR spectrometer, for example, JNM-ECA800 manufactured by JEOL Ltd. can be used. In the measurement of the ²⁹Si NMR spectrum, for example, the cumulative number of times is set to 3500, and the measurement range is set to −500 ppm or more and 500 ppm or less.

Next, the byproduct is analyzed by mass spectrometry (MS) to obtain a mass spectrum. As the analysis sample, for example, a solution obtained by dissolving the byproduct in toluene subjected to degassing and a dehydration treatment is used. The concentration of the byproduct in the solution is 5 mass %, and the water content is 0.6 ppm or less. In the degassing and the dehydration treatment of toluene, for example, a purification apparatus VAC SOLVENT PURIFIER 103991 manufactured by VAC, Inc. is used. As the mass spectrometer, for example, a solarix 9.4T manufactured by Bruker Daltonics is used. As an ionization method, an APCI (Atmospheric Pressure Chemical Ionization) method is used. In the measurement of the mass spectrum, for example, the cumulative number of times is set to 300, and the measurement range is set to 100 to 2000 m/z.

When both of the following requirements (1) and (2) are satisfied from these analysis results, the mixture can be presumed to contain halosilanes having a cyclic structure.
Requirement (1): In the ²⁹Si NMR spectrum, a signal with the greatest relative intensity appears at a position of −0.4 ppm. From the data provided in Non-Patent Literature 1 (Frank Meyer-Wegner, Andor Nadj, Michael Bolte, Norbert Auner, Matthias Wagner, Max C. Holthausen, and Hans-Wolfram W. Lerner, “The Perchlorinated Silanes Si₂Cl₆ and Si₃Cl₈ as Sources of SiCl₂”, Chemistry A European Journal, Apr. 18, 2011, Volume 17, Issue 17, p. 4715-4719), a signal appearing at the position of −0.4 ppm is presumed to belong to a SiCl₃ unit or a SiCl₂ unit.
Requirement (2): In the mass spectrum, signals including (SiCl₂)ₙ are detected over a mass-to-charge ratio range of about 0 to 1500 m/z. For example, signals belonging to (SiCl₂)ₙ are detected in a range of 391 to 1545 m/z.

That is, from the requirement (1), it can be considered that the mixture contains a substance having a molecular framework constituted by a SiCl₂ unit and a SiCl₃ unit, as a main component. From the requirement (2), it can be considered that the mixture contains a substance having a mass ratio between silicon and chlorine of 1:2. The composition formula of such a substance is considered to be (SiCl₂)ₙ, where n is 3 to 15. (SiCl₂)ₙ is expressed as, for example, Si₆Cl₁₂, Si₁₄Cl₂₈, and Si₁₅Cl₃₀. As the compound having such a mass ratio, there may be a compound having either a Si═Si bond or a cyclic structure. However, since a Si═Si bond is highly unstable and immediately decomposes at ambient temperature, a substance having the above mass ratio is not considered to have a Si═Si bond, and thus is considered to have a cyclic structure. Therefore, a substance having this mass ratio is considered to have a cyclic structure.

A hydrolysate can be obtained by making the halosilanes come into contact with water. The hydrolysate may be in the form of a solid. The hydrolysate may be in the form of a mass or particulates.

The hydrolysate may include a compound having at least one of a siloxane bond (Si—O—Si) or a silanol group (—Si—OH). The hydrolysate may also include a hydrasilanol group (—Si(H) OH). The hydrolysate having at least one of the siloxane bond or the silanol group can be presumed by nuclear magnetic resonance spectroscopy described below.

First, a byproduct is collected in the same manner as described above. Pure water is added into a petri dish including the byproduct in a fume hood under air atmosphere, thereby obtaining a mixture of the byproduct and the pure water. The amount of pure water is, for example, 1 mL for 50 mg of the byproduct. Note that the pure water is water having a specific resistance of 18.2 MΩ·cm or more. The mixture is stirred with a spatula made of a fluororesin or the like, and then the petri dish is covered with a lid and the mixture is left alone for 1 hour or more. Thereafter, the lid of the petri dish is removed, and the mixture is left alone for 24 hours or more at ambient temperature to allow water to volatilize from the mixture. The solid matter thus obtained is pulverized with a spatula made of fluororesin or the like to obtain a powder. The powder is dried for 2 hours or more under reduced pressure of 5 Pa or less by a vacuum pump to obtain a measurement sample.

Next, the measurement sample is dispensed into a 3.2 mm zirconia sample tube (708239971) manufactured by JEOL Ltd. This NMR sample tube is set in an NMR spectrometer, and a ²⁹Si NMR spectrum is measured. As the NMR spectrometer, for example, JNM-ECA800 manufactured by JEOL Ltd. can be used. In the measurement of the ²⁹Si NMR spectrum, for example, the cumulative number of times is set to 4096, and the measurement range is set to −250 to 250 ppm.

In the ²⁹Si NMR spectrum of the hydrolysate thus obtained, a peak appearing in the range of −120 to −10 ppm is considered to be derived from at least one of a siloxane bond or a silanol group. Therefore, when the spectrum has a peak within this range, the hydrolysate can be presumed to have at least one of the siloxane bond or the silanol group.

Further, by combining the analysis result of the nuclear magnetic resonance spectroscopy thus obtained with the result of the elemental analysis, the structural formula of the hydrolysate can be presumed.

In the elemental analysis, quantitative analysis is performed on carbon (C), hydrogen (H), nitrogen (N), halogen elements, and sulfur(S) included in the byproduct. The halogen elements are fluorine (F), chlorine (Cl), and bromine (Br). In the analysis of carbon, hydrogen, and nitrogen, for example, JM-11 manufactured by J-Science Lab Co., Ltd. is used. In the analysis of halogen and sulfur, for example, YHS-11 manufactured by Yanaco Corporation is used.

In a case where the elemental analysis result obtained for the hydrolysate shows that the abundance ratio of hydrogen is 1 mass % to 10 mass % and the abundance ratio of the halogen elements is 20 mass % or less, it can be said that the amount of halogen in the byproduct has decreased and the amount of hydrogen has increased through the hydrolysis. The abundance ratio of hydrogen may be 1 mass? to 4 mass %, and the abundance ratio of the halogen elements may be 1.5 mass % or less. From the above-described result of the ²⁹Si NMR spectrum, the increased hydrogen is considered to be derived from Si—OH bonds. Thus, the halogen in the byproduct is considered to be substituted by a hydroxyl group through the hydrolysis of the byproduct. Furthermore, from the abundance ratio of hydrogen falling within the above-described range, the hydrolysate consisting of silicon, oxygen, and hydrogen is presumed to have the following structural formulae (24) to (27).

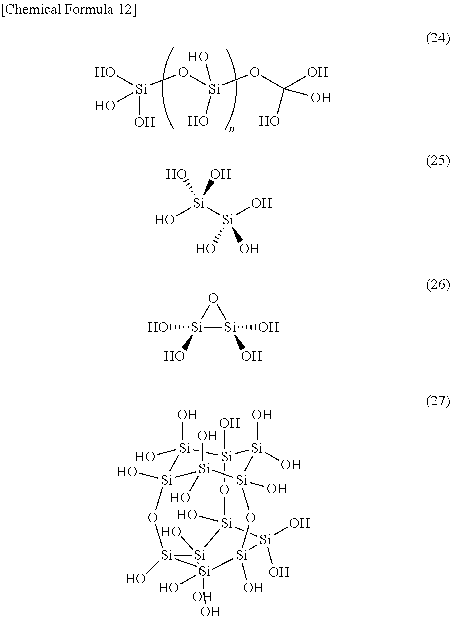

The compounds represented by the structural formulae (24), (26) and (27) have both the siloxane bond and the silanol group. The compounds represented by the structural formulae (24) to (27) are polysilanols having two or more silanol groups.

In the compound of the structural formula (24), the abundance ratio of hydrogen is 2.961 mass %. In the compound of the structural formula (25), the abundance ratio of hydrogen is 3.82 mass %, the abundance ratio of oxygen is 60.67 mass %, and the abundance ratio of silicon is 35.50 mass %. In the compound of the structural formula (26), the abundance ratio of hydrogen is 2.88 mass %, the abundance ratio of oxygen is 57.06 mass %, and the abundance ratio of silicon is 40.07 mass %. In the compound of the structural formula (27), the abundance ratio of hydrogen is 2.63 mass %, the abundance ratio of oxygen is 48.61 mass %, and the abundance ratio of silicon is 48.76 mass %.

The siloxane bond and the Si—Si bond included in the hydrolysate may cause explosiveness or flammability. In particular, the cyclic siloxane bonds included in the structural formulae (26) or (27), and the cyclic silicon ring included in the structural formula (27) upon cleaving can release a large amount of energy. Therefore, compounds including these rings are considered to exhibit flammability.

When the hydrolysates come into contact with the treatment liquid according to the embodiment, the Si—H bond, the siloxane bond, and the Si—Si bond can be cleaved, which can render the hydrolysates harmless in a safe manner.

The mixture may include siloxanes, silica, or the like. The siloxanes contain a Si—O or Si—O—Si bond.

The mixture including the siloxanes can be confirmed by Fourier transform infrared (FT-IR) spectroscopy. That is, in a case where a peak belonging to Si—O—Si is detected in the infrared spectrum, the mixture can be presumed to contain siloxanes. In the infrared spectrum, the peak belonging to Si—O—Si is detected, for example, in a range of 900 cm⁻¹ to 1700 cm⁻¹, and according to another example, is detected in a range of 900 cm⁻¹ to 1300 cm⁻¹.

Specifically, first, a byproduct as a mixture is collected in the same manner as described above. Next, an infrared spectrum of the byproduct is obtained by a single-reflection attenuated total reflection (ATR) method. The infrared spectroscopy is performed with an infrared spectroscopic analyzer placed in a glove box purged with nitrogen. As the infrared spectroscopy analyzer, for example, ALPHA manufactured by Bruker Optics Inc. is used. As the ATR crystal, germanium (Ge) is used. As the analysis conditions, for example, the incident angle is set to 45°, the cumulative number of times is set to 512, the measurement range is set to 500 cm⁻¹ to 4000 cm⁻¹, and the resolution is set to 4 cm⁻¹.

The mixture that may include at least one of halosilanes or hydrolysates may be included in, for example, a byproduct of a reaction that forms a silicon-containing substance using a gas that includes silicon and a halogen element. Specifically, the mixture can be produced by the reaction described below. FIG. 1 shows an example of an epitaxial growth apparatus (silicon-containing substance forming apparatus) as an apparatus in which a mixture that may contain the halosilanes or the hydrolysates is produced. An epitaxial growth apparatus 1 of an example of FIG. 1 includes an apparatus main body 2, an abatement device 3, and a connection portion 5. The apparatus main body 2 includes a housing 6, a reaction chamber 7, a discharge pipe 8, and a supply pipe (not shown). The reaction chamber 7, the discharge pipe 8, and the supply pipe are housed in the housing 6. One end of the supply pipe is connected to the reaction chamber 7. The other end of the supply pipe is connected to a supply device (not shown) including a supply source of a material gas which is a material substance.

One end of the discharge pipe 8 is connected to the reaction chamber 7. The other end of the discharge pipe 8 is connected to the connection portion 5. The discharge pipe 8 includes (five in the example of FIG. 1) pipes 11 to 15. In the apparatus main body 2, the pipes 11, 12, 13, 14, and 15 are arranged in this order from the proximal side (upstream side) with respect to the reaction chamber 7. A chamber isolation valve (CIV) 16 is disposed in the pipe 12, and a pressure control valve (PCV) 17 is disposed in the pipe 13. In a state where the chamber isolation valve 16 is closed, it is possible to perform maintenance only on a portion of the discharge pipe 8 on the side (downstream side) opposite to the reaction chamber 7 with respect to the chamber isolation valve 16. One end of the connection portion 5 is connected to the pipe 15 of the discharge pipe 8. The other end of the connection portion 5 is connected to the abatement device 3. The connection portion 5 includes (two in the example of FIG. 1) pipes 18 and 19. In the epitaxial growth apparatus 1, the pipes 18 and 19 are arranged in this order from the proximal side (upstream side) with respect to the apparatus main body 2.

In the epitaxial growth apparatus 1, a material gas is supplied as a material substance from the supply device through the supply pipe and introduced into the reaction chamber 7. The material gas is a gas containing silicon and a halogen element. Therefore, the material gas contains silicon and one or more kinds of halogen elements. The gas containing silicon and a halogen element is, for example, a mixed gas of hydrogen and a compound containing silicon and a halogen element. The concentration of hydrogen in the mixed gas is, for example, 95 vol % or more. The compound containing silicon and a halogen element includes one or more compounds selected from the group consisting of a compound containing silicon and chlorine, a compound containing silicon and bromine, a compound containing silicon and fluorine, and a compound containing silicon and iodine. The compound containing silicon and a halogen element includes halosilanes.

The compound containing silicon and chlorine is, for example, any one of chlorosilanes such as dichlorosilane (SiH₂Cl₂), trichlorosilane (SiHCl₃), and tetrachlorosilane (SiCl₄), or a mixture thereof. In a case where the compound containing silicon and chlorine is contained in the mixed gas, the mixed gas may contain at least one of monosilane (SiH₄) or hydrogen chloride (HCL). The compound containing silicon and bromine is, for example, one of bromosilanes such as dibromosilane (SiH₂Br₂), tribromosilane (SiHBr₃), and tetrabromosilane (SiBr₄), or a mixture thereof. In a case where the compound containing silicon and bromine is contained in the mixed gas, the mixed gas may contain at least one of monosilane (SiH₄) or hydrobromic acid (HBr).

The material gas may contain two or more kinds of halogen elements, and the material gas may contain, in addition to chlorine, one or more kinds of halogen elements other than chlorine. In one example, the material gas is a mixed gas of a compound containing silicon and chlorine, hydrogen gas, and at least one of a compound containing a halogen element other than chlorine or a halogen gas other than chlorine gas. The compound containing a halogen element other than chlorine may contain silicon or may not contain silicon. In another example, the material gas is a mixed gas of a compound containing silicon and a halogen element other than chlorine, hydrogen gas, and at least one of a compound containing chlorine or chlorine gas. The compound containing chlorine may contain silicon or may not contain silicon.

The reaction chamber 7 can be depressurized by the pressure control valve 17. The reaction chamber 7 is depressurized by the pressure control valve 17, and thus the pressure in the discharge pipe 8 increases in a region on the opposite side of the reaction chamber 7 with respect to the pressure control valve 17, compared to a region on the reaction chamber 7 side with respect to the pressure regulating valve 17. In the epitaxial growth apparatus 1, the substrate is placed in the reaction chamber 7 in a state where the pressure in the reaction chamber 7 is reduced. In the reaction chamber 7, the material gas supplied through the supply pipe reacts with the substrate. At this time, the substrate is heated to a temperature equal to or higher than the reaction temperature with the material gas. An example of the reaction temperature is 600° C. or more, and another example of the reaction temperature is 1000° C. or more. Through the thermochemical reaction between the substrate and the material gas under reduced pressure and at high temperature as described above, a monocrystalline or polycrystalline silicon-containing film is formed on the substrate. The substrate is, for example, a monocrystalline silicon substrate.

The exhaust gas, which is the exhaust substance from the reaction chamber 7, is discharged to the abatement device 3 via the discharge pipe 8 and the connection portion 5. Thus, the discharge pipe 8 and the connection portion 5 form a discharge path from the reaction chamber 7. The exhaust gas may contain a part of the compound containing silicon and a halogen element which is contained in the material gas but has not been deposited on the substrate. Therefore, the exhaust gas may contain a part of the halosilanes contained in the material gas which have not been deposited on the substrate. The exhaust gas may contain an unreacted part of the compound containing silicon and a halogen element that is contained in the material gas and that has not reacted in the reaction chamber 7. The exhaust gas may contain halosilanes produced in the reaction chamber 7 by the reaction of the compound containing a halogen element and silicon. Furthermore, the exhaust gas, which is the exhaust substance, may contain monosilane (SiH₄) described above, and may contain a hydrogen halide such as hydrogen chloride (HCL) and hydrobromic acid (HBr) described above. The exhaust gas is burnt in the abatement device 3 and rendered harmless.

The byproduct produced in the reaction between the material gas and the substrate may be precipitated in part of the discharge pipe 8 and part of the connection portion 5. The byproduct is a solid or liquid formed by reaction of the components contained in the exhaust gas described above. For example, the halosilanes contained in the exhaust gas may react with each other in the discharge pipe 8 or the connection portion 5 to produce a byproduct. In addition, the halosilanes may react with other components contained in the exhaust gas in the discharge pipe 8 or the connection portion 5 to produce a byproduct. Since the byproduct is produced as described above, the byproduct includes the halosilanes described above. The produced byproduct may adhere to the inner surfaces of the pipes 11 to 15 of the discharge pipe 8, the inner surface of the pipes 18 and 19 of the connection portion 5, and the like.

Here, the temperature is high in the pipes 11 and 12 and the like located near the reaction chamber 7. The region on the reaction chamber 7 side with respect to the pressure control valve 17, for such as the pipes 11 and 12, is depressurized as in the reaction chamber 7. Therefore, in the region on the reaction chamber 7 side with respect to the pressure control valve 17, for such as the pipes 11 and 12, it is considered that the polymerization of the components contained in the exhaust gas is unlikely to occur and a byproduct is unlikely to be produced.

As described above, the pressure increases in a region on the opposite side of the reaction chamber 7 with respect to the pressure control valve 17, compared to a region on the reaction chamber 7 side with respect to the pressure regulating valve 17. Therefore, in the pressure control valve 17, the pressure is increased on the downstream side relative to the upstream side. Accordingly, in the region adjacent to the downstream side of the pressure control valve 17, it is considered that the reaction between the components contained in the exhaust gas is likely to proceed, and the byproduct is easily produced. Therefore, it is considered that the byproduct is easily produced particularly in the portion of the pipe 13 on the downstream side of the pressure control valve 17 and in the pipe 14. The reaction described above between the components contained in the exhaust gas is unlikely to occur under reduced pressure.

In addition, in the pipe 15, the connection portion 5, and the like which are separated from the pressure control valve 17 on the downstream side, the amount of components which are raw materials of the byproduct in the exhaust gas is reduced. Therefore, it is considered that the byproduct is unlikely to be produced in the pipe 15, the connection portion 5, and the like.

The byproduct may include, in addition to halosilanes, hydrolysates that may be produced by the halosilanes coming into contact with water. The byproduct may also include silica.

In the treatment method of the embodiment and the like to be described later, the aforementioned byproduct may be a treatment target mixture. At this time, the pipes 11 to 15, 18, and 19 on which the byproduct is deposited are used as the treatment target members. Therefore, the treatment target members include the byproduct. In particular, the byproduct adhering to the pipes 13, 14, etc., on which the byproduct is considered to be easily deposited, are treated by the treatment method of the embodiment or the like to be described later. As described above, the mixture containing the halosilanes or the hydrolysates of the halosilanes may be changed into an explosive substance in the air. Therefore, it is necessary to render the mixture harmless. According to the embodiment, a treatment method for rendering the mixture harmless is provided.

The apparatus described above, in which the mixture containing the halosilanes or the hydrolysates of the halosilanes is produced, is not limited to the epitaxial growth apparatus. In the silicon-containing substance forming apparatus of one working example, the material substance containing silicon and the material substance containing a halogen element are supplied to the reaction chamber (7, for example) through different routes. Here, the material substance containing silicon may contain silicon in a powder form (solid form). The material substance containing a halogen element may be a material gas containing a hydrogen halide such as hydrogen chloride.

In the silicon-containing substance forming apparatus, a substrate such as a silicon substrate is not provided in the reaction chamber (7, for example). In the reaction chamber, the silicon-containing material substance and the halogen-containing material substance, which are separately introduced, react with each other. The halosilanes and hydrogen are produced by the reaction of the silicon-containing material substance and the halogen-containing material substance. Then, a silicon-containing substance is obtained by reaction of the halosilanes and hydrogen. The halosilanes produced by the reaction of the silicon-containing material substance and the halogen-containing material substance may include chlorosilanes such as trichlorosilane (SiHCl₃). In addition, in the reaction in the reaction chamber, hydrogen halide, silicon tetrahalide, and the like may be produced.

In the silicon-containing substance forming apparatus, the exhaust gas (exhaust substance) exhausted from the reaction chamber also contains halosilanes, and the halosilanes contained in the exhaust gas may contain chlorosilanes such as trichlorosilane described above. The exhaust gas from the reaction chamber may contain hydrogen, and may also contain hydrogen halide, silicon tetrahalide, and the like generated by the reaction in the reaction chamber. The hydrogen halide produced in the reaction in the reaction chamber may contain hydrogen chloride (HCl). The silicon tetrahalide generated by the reaction in the reaction chamber may include silicon tetrachloride (SiCl₄).

In the silicon-containing substance forming apparatus, a cooling mechanism for cooling the exhaust gas is provided in the discharge path (discharge pipe 8) for the exhaust gas (exhaust substance) from the reaction chamber. The exhaust gas is cooled by the cooling mechanism and is thereby liquefied. Then, a liquid substance (exhaust substance) obtained by liquefying the exhaust gas is collected.

In the silicon-containing substance forming apparatus, the byproduct may also be precipitated in the discharge path by the exhaust gas being liquefied by the cooling mechanism. The byproduct may include a part of the liquid substance of the exhaust gas that remains in the discharge path without being collected. The byproducts may include the halosilanes contained in the exhaust gas and the hydrolysates of the halosilanes. The hydrolysates of the halosilanes may be a solid substance. The byproduct may include silicon tetrahalide and the like contained in the exhaust gas. In addition, in the discharge path, the byproduct is likely to be precipitated particularly in the cooling mechanism and the vicinity thereof.

As described above, in the silicon-containing substance forming apparatus, a mixture containing the halosilanes and/or the hydrolysates of halosilanes may also be precipitated as the byproduct in, for example, the discharge path. The mixture produced as the byproduct in the silicon-containing substance forming apparatus may also be changed into an explosive substance under air atmosphere. Therefore, it is necessary to render the byproduct harmless, and according to the embodiment, a treatment method for rendering the mixture harmless is provided.

The treatment method of the embodiment is characterized in that a mixture containing one or both of halosilanes and hydrolysates of the halosilanes is treated by bringing the mixture into contact with a treatment liquid at pH 8 to pH 14 in a mass corresponding to 100 times or more the mass of the mixture. According to this method, the reaction during the rendering-harmless treatment becomes moderate, and the temperature rise during the treatment can be suppressed, so that the treatment can be performed safely.

The mechanism of the rendering-harmless treatment will be described by taking, as an example, a case in which an oily silane such as (SiCl₂) n is used as the mixture and a basic aqueous solution is used as the treatment liquid. When the oily silane is brought into contact with the basic aqueous solution, a first reaction shown in a formula (1) occurs.

$${( {SiCl}_{2} )}_{n} + {}_{m} {H}_{2} O \to a {Si}_{x} {O}_{y} {H}_{z} + 2 n HCl + m - az / 2 {H}_{2} \qquad [ Chemical Formula 13 ]$$

The reaction of the oily silane and water represented by the first reaction is an exothermic reaction. The hydrogen chloride produced in the first reaction reacts with a base (BOH) as shown in a formula (2) (second reaction). In the second reaction, heat of neutralization is generated.

$$HCl + BOH \to {H}_{2} O + BCl \qquad [ Chemical Formula 14 ]$$

The hydrolysates produced in the first reaction are rendered harmless according to a third reaction represented by a formula (3). This is because the Si—Si bond and the siloxane bond are cleaved, and as a result, the explosive property is not exhibited.

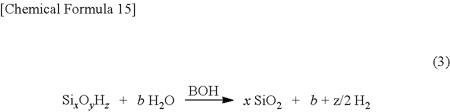

The reason why the pH of the treatment liquid is set to be in the range of 8 to 14 will be described. The basic treatment liquid having a pH that falls within this range can decompose halosilanes and hydrolysates thereof without newly producing explosive substances. For example, Si—Si bonds and Si—X bonds (X is at least one halogen element) in halosilanes having a cyclic structure are cleaved. On the other hand, in the hydrolysates, Si—Si bonds and siloxane bonds are cleaved. Thus, the treatment liquid after the reaction contains substantially no explosive or combustible substance. In addition, during this reaction treatment, hydrogen halide (for example, HCl) may be generated as shown in the above formula (1). Therefore, the pH of the treatment liquid tends to be low during the reaction treatment. By using a basic treatment liquid that falls within the aforementioned range of pH, the hydrogen halide can be neutralized as shown in the formula (2), and therefore, the pH of the treatment liquid can be prevented from being lowered. The pH is more preferably in the range of 8 to 13.

By setting the mass of the basic treatment liquid that falls within the aforementioned ranges of the pH to 100 times or more the mass of the mixture, the heat capacity of the treatment liquid can be increased. Thus, the temperature rise due to the reaction heat can be suppressed. As a result, the reaction proceeds slowly, so that the generated hydrogen is diffused and exhausted smoothly, and the hydrogen can be prevented from remaining in the reaction system. In addition, since the mass of the treatment liquid is large, in a case where a strong base having a base dissociation constant Kb of more than 1 is used, the concentration of the base can be decreased. As a result, since the neutralization reaction of the formula (2) proceeds moderately, the rate of reaction of the subsequent formula (3) can be reduced. Further, since the neutralization reaction of the formula (2) proceeds moderately, the concentration of hydrogen halide in the treatment liquid increases, and therefore the reaction of the formula (1) also proceeds moderately. Therefore, the reaction rate of the series of reactions from the formula (1) to the formula (3) is reduced, and thus the temperature rise during the treatment can be suppressed. On the other hand, in a case where a weak base having a base dissociation constant Kb of less than 1 is used, even if the base concentration of the treatment liquid is increased, the temperature rise during the treatment can be suppressed because the heat capacity of the treatment liquid is large. Therefore, the rendering-harmless treatment can be safely performed regardless of the base dissociation constant Kb.

The pH of the treatment liquid is preferably 8 to 14 before and after the treatment. If the pH after the treatment is less than 8, the neutralization reaction (2) may not be completed. Therefore, the reaction (3) for rendering-harmless treatment following that treatment may not be completed.

On the other hand, in a case where a neutral aqueous solution is used as the treatment liquid, a substance having explosiveness or combustibility may be generated. This is considered to be because, if the mixture containing halosilanes is reacted with the neutral aqueous solution, only the surface of the mixture is hydrolyzed, and the halosilanes present inside the mixture are not decomposed. Alternatively, it is considered to be because if the mixture is reacted with water, the Si—Cl bond in the mixture may be cleaved by hydrolysis, while a product having at least one of a Si—Si bond, a Si—O—Si bond, and a Si—OH bond is generated. In addition, in a case where a neutral or acidic aqueous solution is used, hydrogen halide (for example, hydrogen chloride) cannot be neutralized, and thus the pH of the treatment liquid after the reaction treatment becomes very low, and the treatment liquid may be corrosive. Based on the above, if a neutral or acidic aqueous solution is used, the safety is inferior to that of a method using a basic aqueous solution that falls within the aforementioned range of the pH.

As described above, according to the embodiment, a mixture containing one or both of halosilanes and hydrolysates of the halosilanes can be safely rendered harmless without causing explosion.

The mass of the treatment liquid may be increased to 100 times or more the mass of the mixture, but if it is too large, the treatment time becomes longer due to a decrease in the concentration of the treatment liquid, or the container (for example, a tank) for storing the treatment liquid becomes larger, and the treatment apparatus becomes larger. In order to improve the cost or efficiency required for the treatment, the mass of the treatment liquid is desirably 10,000 times or less the mass of the mixture.

The mass of the mixture containing one or both of halosilanes and hydrolysates of the halosilanes is determined by subtracting the mass of a member (e.g., a pipe) from the total mass of the member and the mixture in a state where the mixture is accommodated in or adhering to the member. On the other hand, the mass of the treatment liquid is obtained from the volume of the treatment liquid by assuming that the specific gravity of the treatment liquid is 1.

In order to react the mixture with the treatment liquid, the mixture is preferably collected under an inert atmosphere. In order to maintain the mixture under an inert atmosphere until immediately before the reaction, the mixture is preferably reacted with the treatment liquid under an inert atmosphere. By managing the mixture under an inert atmosphere, it is possible to prevent the reaction with water or oxygen not only in the inside of the mass of the mixture but also on the surface thereof. The inert gas is, for example, nitrogen gas, argon gas, or a mixed gas thereof. In the inert atmosphere, the dew-point is preferably −50° C. or lower, and the oxygen concentration is preferably 10 ppm or less.

In the treatment method, as a method of bringing the treatment liquid into contact with the mixture, the treatment liquid may be introduced into the mixture, or the mixture may be introduced into the treatment liquid. It is desirable to introduce the mixture into the treatment liquid because the reaction is more moderate in this case. The treatment may be performed in multiple stages. That is, first, a mixture containing halosilanes is reacted with water to cause a hydrolysis reaction of the halosilanes. Water may be introduced into the mixture, or the mixture may be introduced into water. The hydrolysis treatment provides a primary treated product which contains a mixture containing hydrolysates of the halosilanes and water. The primary treated product may contain unreacted halosilanes. Then, the primary treated product is brought into contact with the treatment liquid to perform the treatment. The reaction field for the treatment may be the same as or different from the reaction field for the hydrolysis treatment.

When the mixture and the treatment liquid are reacted, a hydrogen (H₂) gas may be generated. Therefore, this treatment is preferably performed in a facility provided with a gas exhaust mechanism. For example, a duct, a fan, a pump, or the like is used as the gas exhaust mechanism. Preferably, the mixture and the treatment liquid together are subjected to ultrasonic treatment using an ultrasonic cleaner. That is, by vibrating the mixture and the treatment liquid with ultrasonic waves, the dispersibility of the mixture in the treatment liquid can be increased without using a stirring rod or the like. The frequency of the ultrasonic waves is preferably 20 kHz or higher.

Here, the mixture can be deposited as a highly viscous liquid substance on pipes. Therefore, it is considered that halosilanes having a cyclic structure present on the surface of the deposit of the mixture react with water or oxygen to be decomposed into compounds having no Si—Si bond. On the other hand, the chlorosilanes having a ring structure containing a Si—Si bond, which are present inside the deposit of the mixture, are unlikely to come into contact with water or oxygen, and therefore, it is considered that the chlorosilanes maintain the ring structure even under air atmosphere. Therefore, the treatment of the mixture with the basic treatment liquid is effective even under air atmosphere.

Next, a treatment liquid usable in this treatment method will be described.

The treatment liquid is a basic aqueous solution containing at least one of an inorganic base or an organic base. A concentration of the inorganic base and the organic base in the treatment liquid is, for example, 0.01 mass % to 30 mass %, preferably 0.1 mass % to 10 mass %.

As the inorganic base, for example, at least one selected from the group consisting of a metal hydroxide, an alkali metal, a carbonate, a hydrogencarbonate, and a metal oxide is used.

The metal hydroxide is, for example, lithium hydroxide, sodium hydroxide, potassium hydroxide, rubidium hydroxide, cesium hydroxide, calcium hydroxide, magnesium hydroxide, copper hydroxide, iron hydroxide, zinc hydroxide, aluminum hydroxide, or a mixture thereof.

The alkali metal is, for example, a single metal that is potassium, a single metal that is lithium, a single metal that is sodium, or a mixture thereof.

The carbonate is, for example, sodium carbonate, potassium carbonate, ammonium carbonate, potassium carbonate, lithium carbonate, barium carbonate, magnesium carbonate, or a mixture thereof.

The hydrogencarbonate is, for example, sodium hydrogencarbonate, ammonium hydrogencarbonate, potassium hydrogencarbonate, calcium hydrogencarbonate, or a mixture thereof.

The metal oxide is, for example, calcium oxide, magnesium oxide, sodium oxide, or a mixture thereof.

The inorganic base includes, for example, at least one selected from the group consisting of a hydroxide of an alkali metal element, a carbonate of an alkali metal element, a hydrogencarbonate of an alkali metal element, a hydroxide of an alkaline earth metal element, a carbonate of an alkaline earth metal element, and ammonium hydroxide (NH₄OH).

The inorganic base is preferably at least one selected from the group consisting of sodium hydroxide (NaOH), potassium hydroxide (KOH), sodium carbonate (Na₂CO₃), calcium hydroxide (Ca(OH)₂), lithium hydroxide (LiOH), sodium hydrogencarbonate (NaHCO₃), and ammonium hydroxide (NH₄OH). Use of such an inorganic base, which is less toxic, can render it possible to treat the mixture more safely.

The inorganic base is more preferably at least one selected from the group consisting of potassium hydroxide (KOH), sodium carbonate (Na₂CO₃), lithium hydroxide (LiOH), sodium hydrogencarbonate (NaHCO₃), and ammonium hydroxide (NH₄OH). Use of such an inorganic base allows the reaction to proceed moderately, which can render it possible to perform the treatment more safely.

As the organic base, for example, at least one selected from the group consisting of alkylammonium hydroxides, an organometallic compound, a metal alkoxide, an amine, and a heterocyclic amine is used.

The alkylammonium hydroxides are, for example, tetramethylammonium hydroxide, tetraethylammonium hydroxide, choline hydroxide, or a mixture thereof.

The organometallic compound is, for example, an organolithium, an organomagnesium, or a mixture thereof. The organolithium is, for example, butyllithium, methyllithium, or a mixture thereof. The organomagnesium is, for example, butylmagnesium, methylmagnesium, or a mixture thereof.

The metal alkoxide is, for example, sodium ethoxide, sodium butoxide, potassium ethoxide, potassium butoxide, sodium phenoxide, lithium phenoxide, sodium ethoxide, or a mixture thereof.

The amine is methylamine, dimethylamine, trimethylamine, triethylamine, ethylenediamine, diethylamine, aniline, or a mixture thereof.

The heterocyclic amine is pyridine, pyrrolidine, imidazole, piperidine, or a mixture thereof.

The organic base is preferably at least one selected from the group consisting of sodium phenoxide (C₆H₅ONa), 2-hydroxyethyltrimethylammonium hydroxide (choline hydroxide), and tetramethylammonium hydroxide (TMAH).

The treatment liquid containing an organic base tends to react more moderately with the mixture than the treatment liquid containing only an inorganic base, and therefore can treat the mixture more safely. The treatment liquid containing an organic base is more suitable for use in a clean room than the treatment liquid containing only an inorganic base. A mixture containing one or both of halosilanes and hydrolysates of the halosilanes are produced in semiconductor manufacturing processes, for example, in an epitaxial growth apparatus. Such a semiconductor manufacturing process is performed in a clean room from which minute dust particles in the air have been removed because even a minute amount of foreign matter adhering to a semiconductor causes a failure such as a defect. In particular, metal foreign matter has a large effect on the quality when it adheres to a semiconductor, and therefore should be thoroughly removed. Further, although ammonia does not contain a metal element, it acts as an inhibitor of a chemically amplified photoresist, and therefore, use of ammonia in a clean room is avoided. The organic base may be one that does not contain any alkaline earth metal or alkali metal element, such as TMAH, or one, such as C₆H₅ONa, in which the proportion of these elements per unit weight is lower than that of the inorganic base. Therefore, in a case of using the treatment liquid containing an organic base, contamination by metal foreign matter or ammonia in the clean room can be suppressed as compared with the case of using the treatment liquid containing only an inorganic base, and thus the semiconductor manufacturing efficiency can be enhanced.

Examples of the base having a base dissociation constant Kb of more than 1 include choline hydroxide, TMAH, and NaOH. Among the bases having a base dissociation constant Kb of more than 1, organic bases such as choline hydroxide and alkylammonium hydroxides such as TMAH are preferable. Since choline hydroxide and TMAH each do not contain any alkaline earth metal element and alkali metal element, it is possible to avoid contamination of the treatment target with these elements.

On the other hand, examples of the base having a base dissociation constant Kb of less than 1 include sodium hydrogen carbonate and sodium phenoxide. Among the bases having a base dissociation constant Kb of less than 1, sodium hydrogen carbonate (NaHCO₃) is preferable. Since sodium hydrogen carbonate has a smaller molecular weight than an organic base having a base dissociation constant Kb of less than 1, the molar concentration of sodium hydrogen carbonate can be increased as compared with an organic base having a base dissociation constant Kb of less than 1 in a case where the mass % concentration is constant. Therefore, the treatment can be smoothly performed.

Water is used as a solvent of the treatment liquid. As the water, pure water, ion-exchanged water, purified water, tap water, or a mixture thereof may be used.

The treatment liquid may include an optional component such as a surfactant, a pH buffer, or the like, in addition to at least one of the inorganic base or the organic base.

The surfactant enhances the dispersibility of the mixture in the treatment liquid and increases the treatment rate. The concentration of the surfactant in the treatment liquid is, for example, 0.01 mass % to 10 mass %, and preferably 0.1 mass % to 1 mass %.

The surfactant includes, for example, at least one selected from the group consisting of an anionic surfactant, a cationic surfactant, an amphoteric surfactant, and a nonionic surfactant.

The anionic surfactant is, for example, sodium laurate, sodium stearate, sodium lauryl sulfate, sodium 1-hexanesulfonate, lauryl phosphate, or a mixture thereof.

The cationic surfactant is, for example, tetramethylammonium chloride, benzalkonium chloride, octyltrimethylammonium chloride, monomethylamine hydrochloride, butylpyridinium chloride, or a mixture thereof.

The amphoteric surfactant is, for example, lauryldimethylaminoacetic acid betaine, cocamidopropyl betaine, sodium lauroyl glutamate, lauryldimethylamine N-oxide, or a mixture thereof.

The nonionic surfactant is, for example, glyceryl laurate, pentaethylene glycol ono-dodecyl ether, polyoxyethylene sorbitan fatty acid ester, lauric acid diethanolamide, octyl glucoside, cetanol, or a mixture thereof.

The surfactant preferably includes at least one of benzalkonium chloride or sodium laurate, and more preferably, benzalkonium chloride is used.

The pH buffer serves to maintain the pH of the treatment liquid constant during the treatment of the mixture. Using the pH buffer can prevent the pH of the solution after the mixture decomposition treatment from becoming excessively high or low. Thus, through use of the pH buffer, the mixture can be rendered harmless more safely.

The concentration of the pH buffer in the treatment liquid is, for example, 0.01 mass % to 30 mass %, and preferably 0.1 mass % to 10 mass %.

As the pH buffer, a mixture of a weak acid and its conjugate base, or a mixture of a weak base and its conjugate acid can be used. Examples of the pH buffer include a mixture of acetic acid (CH₃COOH) and sodium acetate (CH₃COONa), a mixture of citric acid and sodium citrate, or a mixture of trishydroxymethylaminomethane (THAM) and ethylenediaminetetraacetic acid (EDTA).

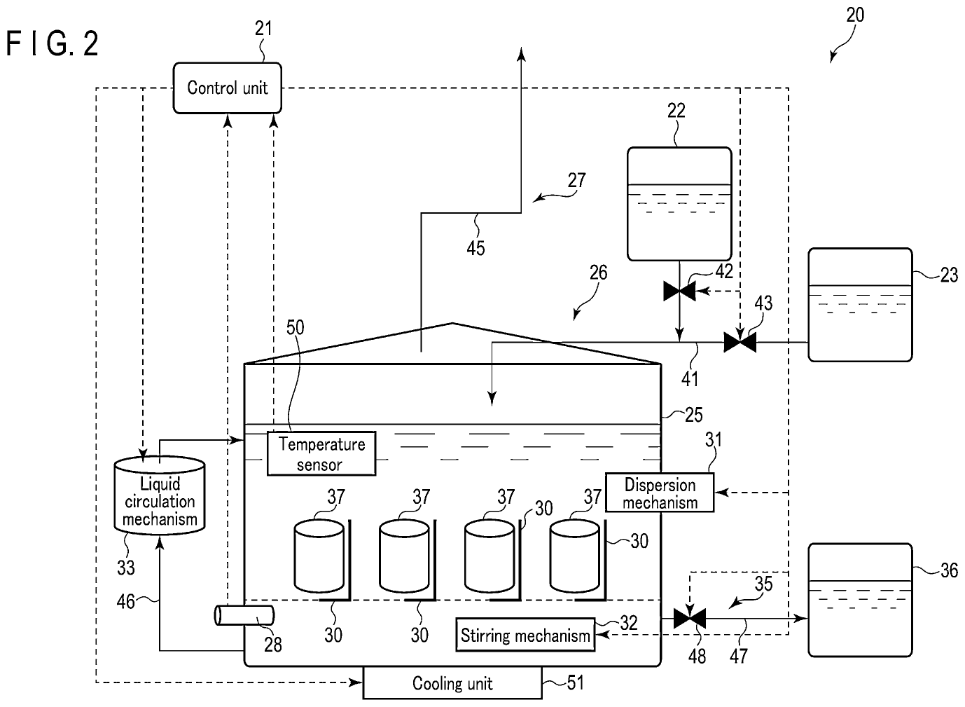

FIG. 2 shows a treatment apparatus 20 for use in the method according to the embodiment as an example of the treatment apparatus for treating the mixture. As shown in FIG. 2, the treatment apparatus 20 includes a control unit (controller) 21, a water solvent tank 22, a treatment liquid tank 23, a treatment tank 25, a supply mechanism (supply system) 26, an exhaust mechanism (exhaust system) 27, a sensor 28, a jig 30, a dispersion mechanism (disperser) 31, a stirring mechanism (stirrer) 32, a liquid circulation mechanism (liquid circulator) 33, a liquid discharge mechanism (liquid discharge system) 35, a waste liquid tank 36, a temperature sensor 50, and a cooling unit 51. In FIG. 2, the flows of fluid such as liquid and gas are indicated by solid arrows, and electrical signals such as input signals to the control unit 21 and output signals from the control unit 21 are indicated by broken arrows.

The control unit 21 controls the overall treatment apparatus 20. The control unit 21 includes a processor or an integrated circuit (control circuit) including a central processing unit (CPU), an application specific integrated circuit (ASIC), a field programmable gate array (FPGA), or the like, and a storage medium such as a memory. The control unit 21 may include only one processor or integrated circuit, or may include a plurality of processors or integrated circuits. The control unit 21 performs processing by executing a program or the like stored in the storage medium. The storage medium also receives and retains temperature measurement value information from the temperature sensor 50. The processor or integrated circuit obtains a temperature variation of the treatment liquid based on the temperature measurement value information read from the storage medium.

The water solvent tank 22 stores a water solvent. The water solvent may be water alone, or a liquid (for example, an aqueous solution) obtained by dissolving or mixing necessary additives in water. Examples of additives include a surfactant, a pH buffer, and the like. The treatment liquid tank 23 stores the treatment liquid. The treatment liquid is used for rendering the mixture harmless. The treatment liquid includes a basic aqueous solution. A treatment target member 37 to which the byproduct as the mixture adheres is introduced into the treatment tank 25. At this time, for example, the pipes 11 to 15, etc. of the example of FIG. 1, to which the byproduct adheres, are introduced into the treatment tank 25 as the treatment target member 37. Thus, the treatment target member 37 includes the byproduct. The discharge pipe 8 is disassembled into pipes, which are introduced into the treatment tank 25.

The supply mechanism (liquid supply mechanism) 26 can supply the water solvent from the water solvent tank 22 to the treatment tank 25 and can supply the treatment liquid from the treatment liquid tank 23 to the treatment tank 25. In the embodiment, the supply mechanism 26 includes a supply line 41 and valves 42 and 43. The supply line 41 is formed of, for example, one or more pipes. In the embodiment, the treatment tank 25 is connected to the water solvent tank 22 and the treatment liquid tank 23 via the supply line 41. Furthermore, in the embodiment, the operation of the valves 42 and 43 is controlled by the control unit 21, and the opening and closing of each of the valves 42 and 43 are switched by the control unit 21.

In a state in which the valves 42 and 43 are closed, neither the water solvent nor the treatment liquid is supplied to the treatment tank 25. When the valve 42 is opened, the water solvent is supplied from the water solvent tank 22 to the treatment tank 25 through the supply line 41. When the valve 43 is opened, the treatment liquid is supplied from the treatment liquid tank 23 to the treatment tank 25 through the supply line 41. In one working example, the control unit 21 switches the opening and closing of each of the valves 42 and 43 based on an operation of an operator on an operation device (not shown) such as a user interface. The switching of the opening and closing of each of the valves 42 and 43 need not be performed by the control unit 21. In another working example, the switching of the opening and closing of each of the valves 42 and 43 may be performed by an operator without using the control unit 21.

In the treatment tank 25, the byproduct deposited on the treatment target member 37 is rendered harmless by the treatment liquid supplied by the supply mechanism 26. In one working example, in treatment rendering the byproduct harmless, the treatment liquid is supplied to the treatment tank 25 after the treatment target member 37 is introduced into the treatment tank 25. In another working example, in treatment rendering the byproduct harmless, the treatment liquid is supplied to the treatment tank 25, and the treatment target member 37 is introduced into the treatment tank 25 in a state where the supplied treatment liquid is stored in the treatment tank 25. In the rendering-harmless treatment, when the treatment liquid is stored in the treatment tank 25 to some extent, the valve 43 is closed to stop the supply of the treatment liquid to the treatment tank 25.

In addition, in the reaction for rendering the byproduct harmless by the treatment liquid described above, a gas is generated. The gas generated by the reaction for rendering the byproduct harmless contains hydrogen. The gas generated by the reaction for rendering the byproduct harmless may contain hydrogen halide such as hydrogen chloride. The exhaust mechanism (gas discharge mechanism) 27 exhausts a gas generated by the reaction between the byproduct and the treatment liquid from the treatment tank 25. The exhaust mechanism 27 includes an exhaust line 45. The exhaust line 45 is formed of, for example, one or more pipes. In the embodiment, the exhaust line 45 is formed to extend from the treatment tank 25 to the outside of a room (environment) where an operator performs work. The gas generated by the reaction for rendering the byproduct harmless is exhausted to the outside of the room where the operator performs the work through the exhaust line 45. In one working example, the gas exhausted to the outside of the room is collected and rendered harmless.

The gas generated by the reaction for rendering the byproduct harmless is mainly hydrogen. Hydrogen is lighter than air. Therefore, the connection portion point between the exhaust line 45 and the treatment tank 25 is preferably provided at a vertically upper portion in an internal space of the treatment tank 25. In one working example, the exhaust mechanism 27 includes a suction source (not shown) such as a suction pump. Then, the gas is exhausted by causing a suction force to act on the internal space of the treatment tank 25 and the exhaust line 45 by the suction source. In this case, the controller 21 may control the driving of the suction source.

The sensor 28 detects a parameter related to the progress of the reaction between the treatment liquid and the byproduct in the rendering-harmless treatment for the byproduct. The sensor 28 may be integrated with the treatment tank 25 or may be detachably attached to the treatment tank 25. In addition, in one working example, the sensor 28 may be provided separately from the treatment tank 25 and may not be mechanically connected to the treatment tank 25. The sensor 28 may include, for example, one or more of a pH measuring device, a Raman spectrometer, an infrared spectroscopy (IR) analyzer, and a nuclear magnetic resonance (NMR) spectrometer. In the embodiment, the sensor 28 comprises a pH measuring device.

In the embodiment, the control unit 21 acquires a detection result of the sensor 28. The control unit 21 determines the progress of the rendering-harmless treatment for the byproduct based on the detection result of the sensor 28, and determines whether the byproduct has been appropriately rendered harmless. In one working example, a notification device (not shown) that gives a notification that the byproduct is appropriately rendered harmless may be provided. In this case, if the control unit 21 determines that the byproduct has been appropriately rendered harmless, the control unit 21 operates the notification device to give a notification that the byproduct has been appropriately rendered harmless. The notification is performed by any one of sound emission, light emission, screen display, and the like. In one working example, the determination of whether or not the byproduct has been appropriately rendered harmless may be performed by an operator instead of the control unit 21. In this case, the operator acquires the detection result of the sensor 28 and determines whether the byproduct has been appropriately rendered harmless based on the acquired detection result.

As described above, hydrogen halide is generated by the reaction between the byproduct and the treatment liquid. The aqueous solution of hydrogen halide is acidic. Therefore, as the rendering-harmless treatment for the byproduct progresses, the pH of the treatment liquid decreases. Thus, since the progress of the reaction between the treatment liquid and the byproduct can be appropriately determined based on the pH of the treatment liquid, the progress of the rendering-harmless treatment can be appropriately determined.

In addition, the bonding state between atoms, the molecular structure, and the like of the components contained in the byproduct may be changed by the reaction between the byproduct and the treatment liquid. Therefore, the progress of the reaction between the treatment liquid and the byproduct can be appropriately determined based on the spectral intensity of any of the Raman spectrum, the IR spectrum, and the NMR spectrum, so that the progress of the rendering-harmless treatment can be appropriately determined.

The jig 30 maintains each of the treatment target members 37 in a predetermined posture in the treatment liquid of the treatment tank 25. At this time, each of the treatment target members 37 such as the pipes to which the byproducts adhere is maintained in a state where one of the openings of each pipe faces vertically upward. That is, each of the treatment target members 37 is maintained in a state where one of the openings of the pipe faces the side where the liquid surface of the treatment liquid is located. As described above, in each of the treatment target members 37 in the treatment liquid, a gas (hydrogen) is generated therein by the reaction for rendering the byproduct harmless. In the embodiment, since the posture of the treatment target members 37 is maintained by the jig 30 as described above, the gas (hydrogen) generated inside each treatment target member 37 is directed to the liquid surface of the treatment liquid through the opening facing the vertically upper side. The gas is then appropriately exhausted from the liquid surface of the treatment liquid through the exhaust line 45. Therefore, the bubbles of the gas generated by the reaction for rendering the byproduct harmless are effectively prevented from remaining in each treatment target member.

In the embodiment, since the posture of the treatment target members 37 is maintained by the jig 30 as described above, the contact between the treatment target members 37 and the contact between each of the treatment target members 37 and the inner wall of the treatment tank 25 are effectively prevented in the treatment liquid. Therefore, in the rendering-harmless treatment for the byproduct, damage to the treatment target members (pipes) 37 is effectively prevented.

The dispersion mechanism 31 disperses the mass (condensed particles) of the byproduct in the treatment liquid in the treatment tank 25 in parallel with the rendering-harmless treatment for the byproduct by the treatment liquid. The stirring mechanism 32 stirs the treatment liquid in the treatment tank 25 in parallel with the rendering-harmless treatment for the byproduct by the treatment liquid. The liquid circulation mechanism 33 forcibly forms a flow of circulating the treatment liquid in the treatment tank 25 in parallel with the rendering-harmless treatment for the byproduct by the treatment liquid. By performing any one of the dispersion of the mass of the byproduct by the dispersion mechanism 31, the stirring of the treatment liquid by the stirring mechanism 32, and the formation of the flow of circulating the treatment liquid by the liquid circulation mechanism 33, the reaction between the byproduct and the treatment liquid is promoted, and the rendering-harmless treatment for the byproduct is promoted.

As the dispersing mechanism 31, for example, any of a high-speed rotation shearing type stirrer, a colloid mill, a roll mill, a high-pressure injection type disperser, an ultrasonic disperser, a bead mill, and a homogenizer can be used. In the high-speed rotation shearing type stirrer, the condensed particles (mass) of the byproduct are passed between a high-speed rotary blade and an outer cylinder, whereby the mass of the byproduct is dispersed. In the colloid mill, the byproduct mass and the treatment liquid are forced to flow together between two rotating surfaces, so that shear force is applied to the treatment liquid. Then, the mass of the byproduct is dispersed by the shear force of the treatment liquid. In the roll mill, the mass of the byproduct (condensed particles) is passed across two or three rotating rolls, so that the mass of the byproduct is dispersed. The high-pressure injection type disperser injects the treatment liquid at a high pressure to a portion of the treatment target member 37 to which the byproduct adheres. As a result, the mass of the byproduct is dispersed by the collision between the treatment liquid and the treatment target member (pipe) 37. The ultrasonic disperser generates ultrasonic vibrations in the treatment liquid and disperses the mass of the byproduct by the generated ultrasonic vibrations. The bead mill uses beads (spheres) as media to disperse the mass of the byproduct. At this time, motion is applied to the beads, and the mass of the byproduct is dispersed by collision between the beads or the like. The homogenizer applies a high pressure to the treatment liquid to generate a homovalve in the treatment liquid. Then, the generated homovalve passes through the inside of the treatment target member 37 and the like, whereby the mass of the byproduct is uniformly dispersed.

As the stirring mechanism 32, either a pump or a rotary spring can be used. The pump forms a flow of the treatment liquid in the treatment liquid in the treatment tank 25 to stir the treatment liquid. The rotary spring rotates in the treatment liquid to stir the treatment liquid. Any of the devices described above for use as the dispersion mechanism 31 can also be used as the stirring mechanism 32. In this case, the aforementioned device stirs the treatment liquid, while dispersing the mass of the byproduct.

A pump can be used as the liquid circulation mechanism 33. In the example of FIG. 2, the liquid circulation mechanism 33 such as a pump is provided in a circulation line 46 formed outside the treatment tank 25. In this case, the liquid circulation mechanism 33 forcibly forms a flow of the treatment liquid circulating through the inside of the treatment tank 25 and the circulation line 46. The treatment liquid is stirred by the flow of circulating the treatment liquid formed in the treatment tank 25. Therefore, the pump or the like to be used as the liquid circulation mechanism 33 is also used as the stirring mechanism 32. The circulation line 46 is formed of one or more pipes and is provided separately from the supply line 41 and a liquid discharge line 47 to be described later. In one working example, the circulation line 46 or the like is not provided outside the treatment tank 25, and the liquid circulation mechanism 33 forcibly forms a flow of circulating the treatment liquid only inside the treatment tank 25.

The control unit 21 controls the operation of each of the dispersion mechanism 31, the stirring mechanism 32, and the liquid circulation mechanism 33. In one working example, the control unit 21 operates each of the dispersion mechanism 31, the stirring mechanism 32, and the liquid circulation mechanism 33 based on an operation of an operator in an operation device (not shown) such as a user interface. Then, the mass of the byproducts is dispersed by the operation of the dispersion mechanism 31, the treatment liquid is stirred by the operation of the stirring mechanism 32, and a flow of circulating the treatment liquid is formed by the operation of the liquid circulation mechanism 33. In another working example, any one of the dispersion mechanism 31, the stirring mechanism 32, and the liquid circulation mechanism 33 may be operated by an operation of the operator or the like without the control unit 21.

The liquid discharge mechanism 35 discharges the treatment liquid reacted with the byproduct in the treatment tank 25 from the treatment tank 25. The waste liquid tank 36 stores the treatment liquid discharged from the treatment tank 25. The liquid discharge mechanism 35 includes the liquid discharge line 47 and a valve 48. The liquid discharge line 47 is formed of, for example, one or more pipes. In the embodiment, the treatment tank 25 is connected to the waste liquid tank 36 via the liquid discharge line 47. In the embodiment, the operation of the valve 48 is controlled by the control unit 21, and the opening and closing of the valve 48 is switched by the control unit 21.

In a state where the valve 48 is closed, the treatment liquid is not discharged from the treatment tank 25. When the valve 48 is opened, the treatment liquid is discharged from the treatment tank 25 to the waste liquid tank 36 through the liquid discharge line 47. In one working example, the control unit 21 switches the opening and closing of the valve 48 based on an operation of an operator on an operation device (not shown) such as a user interface. In this case, when the rendering-harmless treatment for the byproduct is performed in the treatment tank 25, the valve 48 is closed. Upon completion of the rendering-harmless treatment, the control unit 21 opens the valve and discharges the treatment liquid from the treatment tank 25 based on the operation of the operator. Note that the switching of the opening and closing of the valve 48 does not need to be performed by the control unit 21, and in another working example, the switching of the opening and closing of the valve 48 may be performed by the operator without using the control unit 21.

In the embodiment, upon discharge of the treatment liquid from the treatment tank 25, the valve 48 is closed. Then, the valve 42 is opened to supply the water solvent to the treatment tank 25. The treatment target member 37 is cleaned with the water solvent.

The temperature sensor 50 is provided at a position where the temperature of the treatment liquid contained in the treatment tank 25 can be measured. A thermometer can be used instead of the temperature sensor.

The cooling unit 51 cools the treatment liquid contained in the treatment tank 25. The cooling unit 51 may be, for example, a fan for cooling the treatment tank 25 from outside, a refrigerant provided adjacent to the outer wall surface of the treatment tank 25, or the like.

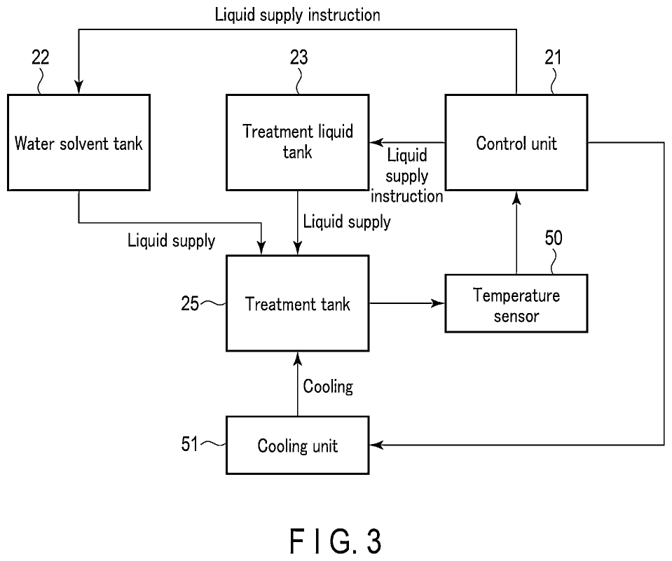

FIG. 3 is a block diagram showing a temperature control mechanism for the treatment liquid in the treatment tank 25. Upon receipt of a signal from the control unit 21, the temperature sensor 50 measures the temperature of the treatment liquid in the treatment tank 25 and inputs the measurement result to the control unit 21 as measurement value information. The storage medium of the control unit 21 retains the measurement value information. The processor or the integrated circuit of the control unit 21 calculates a temperature variation based on the measurement value information. Next, the processor or the integrated circuit of the control unit 21 compares the temperature variation with a reference value (for example, +10° C.) stored in the storage mediums in advance. If the temperature variation exceeds the reference value, the control unit 21 instructs the water solvent tank 22 to supply the water solvent to the treatment tank 25. In addition, if the temperature variation exceeds the reference value, the control unit 21 operates the cooling unit 51 instead of providing the instruction or when providing the instruction. On the other hand, if the temperature variation is equal to or less than the reference value, the control unit 21 instructs the treatment liquid tank 23 to supply the treatment liquid to the treatment tank 25. In another working example, instead of the control unit 21, the operator or the like may instruct the water solvent tank 22 and the treatment liquid tank 23 to supply the liquid and may operate the cooling unit 51.

By the treatment method using the treatment apparatus 20 described above, the mixture containing one or both of the halosilanes and hydrolysates of the halosilanes is safely rendered harmless in the treatment tank 25. Further, the gas (hydrogen) generated by the reaction between the treatment liquid and the mixture is appropriately exhausted by the exhaust mechanism 27. Furthermore, since the parameter related to the progress of the reaction between the treatment liquid and the mixture in the treatment tank 25 is detected by the sensor 28, the progress of the rendering-harmless treatment for the mixture can be appropriately determined based on the detection result of the sensor 28. In addition, by operating any one of the dispersion mechanism 31, the stirring mechanism 32, and the liquid circulation mechanism 33 in parallel with the rendering-harmless treatment for the mixture, the reaction between the mixture and the treatment liquid is promoted, and the rendering-harmless treatment for the mixture is promoted.

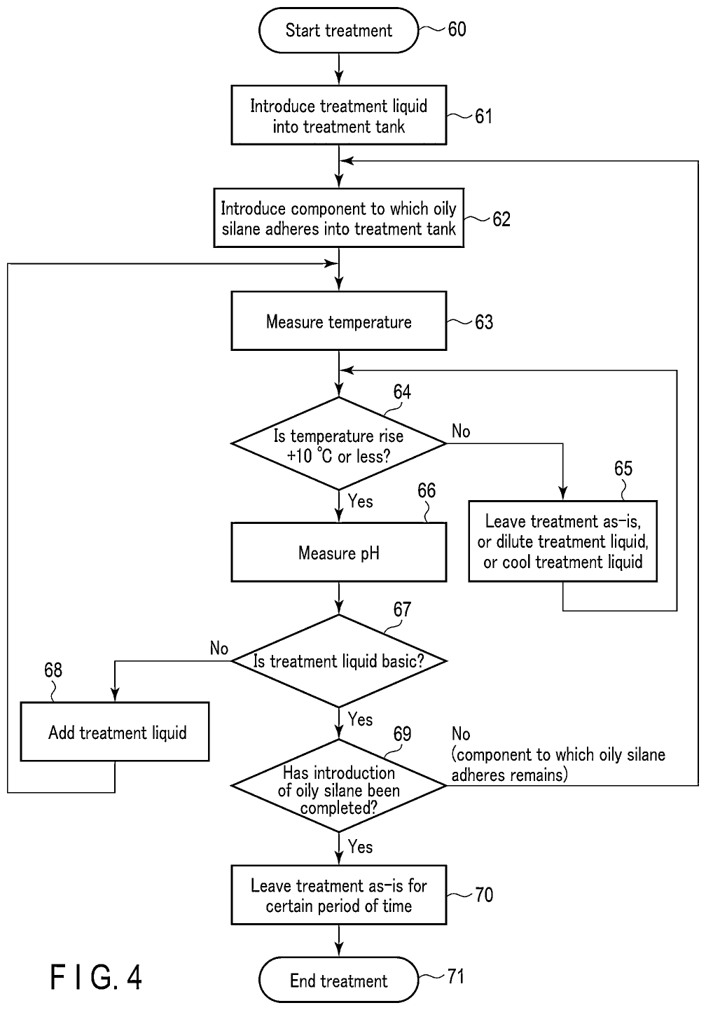

An example of a treatment method using the treatment apparatus described above will be described with reference to FIGS. 4 to 8. FIG. 4 is a flowchart showing a first example of the treatment method.

After a mixture containing one or both of halosilanes and hydrolysates of the halosilanes is deposited as a byproduct in the discharge path or the like of the epitaxial growth apparatus or the like illustrated in FIG. 1, the treatment is started (step 60). A treatment liquid (for example, a chemical liquid) is supplied from the treatment liquid tank 23 to the treatment tank 25 (step 61). A treatment target member 37 (for example, a component to which oily silane adheres) is introduced into the treatment tank 25 (step 62). Then, a rendering-harmless treatment for the byproduct deposited on the treatment target member 37 is started. The temperature of the treatment liquid in the treatment tank 25 is measured by the temperature sensor 50 (step 63). The control unit 21 compares this measured value with an initially measured value, and compares the temperature variation obtained by this comparison with a reference value (for example, +10° C.) (step 64). If the temperature variation exceeds +10° C. (No in step 64), (a) the treatment liquid is left as-is, (b) a water solvent is supplied from the water solvent tank 22 to the treatment tank 25 to lower the base concentration of the treatment liquid, or (c) the treatment liquid in the treatment tank 25 is cooled by the cooling unit 51 (step 65). In step 65, only one of the steps (a) to (c) may be performed, or two or more of the steps (a) to (c) may be performed in combination. For example, the base concentration of the treatment liquid may be lowered while cooling the treatment liquid in the treatment tank 25 by the cooling unit 51. Step 65 is performed until the temperature variation is reduced to +10° C. or less.

If the temperature variation is +10° C. or less (Yes in step 64), the pH of the treatment liquid in the treatment tank 25 is measured by the pH measuring device of the sensor 28 (step 66). If the pH of the treatment liquid is not basic, for example, if the pH is less than 8 (No in step 67), there is a high probability that the rendering-harmless treatment will be stopped in the middle due to the shortage of the basic component. In this case, the treatment liquid is supplied from the treatment liquid tank 23 to the treatment tank 25 (step 68). Thereafter, the process returns to the temperature measurement of the treatment liquid (step 63) in order to continue the rendering-harmless treatment.

If the pH of the treatment liquid is basic, for example, if the pH is 8 to 14 (Yes in step 67), it is checked whether or not there is any untreated treatment target member 37 (for example, a component to which oily silane adheres) that has not been introduced into the treatment tank 25 (step 69). As a result of the check, if there still is an untreated treatment target member 37 (No in step 69), the process starts again from step 62 in which a new treatment target member 37 is introduced into the treatment tank 25. If the rendering-harmless treatment for the byproduct has been completed (Yes in step 69), the treatment target member 37 is left alone for a certain period of time while being immersed in the treatment liquid (step 70). After being left alone, the treatment is ended (step 71).

According to the first example of the method described above, the mixture containing one or both of halosilanes and hydrolysates of the halosilanes is treated by bringing the treatment liquid having a pH of 8 to 14 and having a mass corresponding to 100 times or more the mass of the mixture into contact with the mixture. During this treatment, the temperature variation of the treatment liquid is maintained at 10° C. or less, and the pH of the treatment liquid is maintained in the range of 8 to 14. By maintaining the temperature variation of the treatment liquid during the treatment at 10° C. or less, the treatment can proceed moderately. Further, by maintaining the pH of the treatment liquid during the treatment in the range of 8 to 14, stagnation or stoppage of the treatment in the middle can be avoided. As a result, the treatment can be smoothly performed while suppressing the temperature rise, and thus the rendering-harmless treatment can be safely performed.

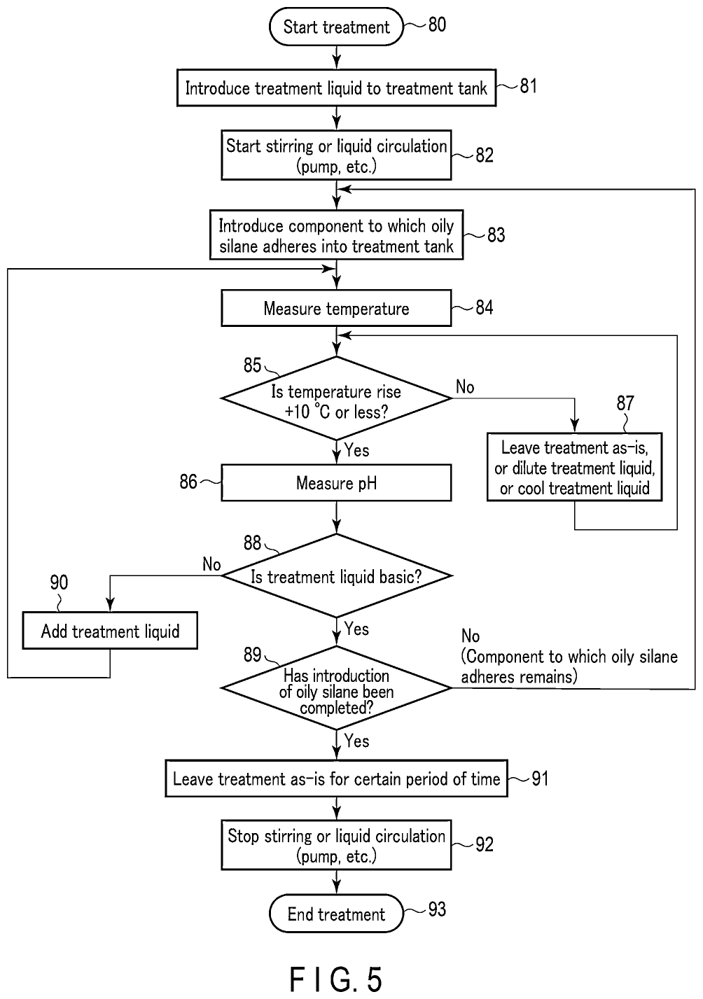

FIG. 5 is a flowchart showing a second example of the treatment method.

After a mixture containing one or both of halosilanes and hydrolysates of the halosilanes is deposited as a byproduct in the discharge path or the like of the epitaxial growth apparatus or the like illustrated in FIG. 1, the treatment is started (step 80). A treatment liquid (for example, a chemical liquid) is supplied from the treatment liquid tank 23 to the treatment tank 25 (step 81). The treatment liquid in the treatment tank 25 is stirred by any one of the dispersion mechanism 31, the stirring mechanism 32, and the liquid circulation mechanism 33 (step 82). A treatment target member 37 (for example, a component to which oily silane adheres) is introduced into the treatment tank 25 while maintaining the stirring (step 83). Then, a rendering-harmless treatment for the byproduct deposited on the treatment target member 37 is started. The temperature of the treatment liquid in the treatment tank 25 is measured by the temperature sensor 50 (step 84). The control unit 21 compares this measured value with an initially measured value, and compares the temperature variation obtained by this comparison with a reference value (for example, +10° C.) (step 85). If the temperature variation exceeds +10° C. (No in step 85), (a) the treatment liquid is left as-is, (b) a water solvent is supplied from the water solvent tank 22 to the treatment tank 25 to lower the base concentration of the treatment liquid, or (c) the treatment liquid in the treatment tank 25 is cooled by the cooling unit 51 (step 87). In step 87, only one of the steps (a) to (c) may be performed, or two or more of the steps (a) to (c) may be performed in combination.

If the temperature variation is +10° C. or less (Yes in step 85), the pH of the treatment liquid in the treatment tank 25 is measured by the pH measuring device of the sensor 28 (step 86). If the pH of the treatment liquid is not basic, for example, if the pH is less than 8 (No in step 88), there is a high probability that the rendering-harmless treatment will be stopped in the middle due to the shortage of the basic component. In this case, the treatment liquid is supplied from the treatment liquid tank 23 to the treatment tank 25 (step 90). Thereafter, the process returns to the temperature measurement of the treatment liquid (step 84) in order to continue the rendering-harmless treatment.

If the pH of the treatment liquid is basic, for example, if the pH is 8 to 14 (Yes in step 88), it is checked whether or not there is any untreated treatment target member 37 (for example, a component to which oily silane adheres) that has not been introduced into the treatment tank 25 (step 89). As a result of the check, if there still is an untreated treatment target member 37 (No in step 89), the process starts again from step 83 in which a new treatment target member 37 is introduced into the treatment tank 25. If the rendering-harmless treatment for the byproduct has been completed (Yes in step 89), the treatment target member 37 is left alone for a certain period of time while being immersed in the treatment liquid (step 91). After being left alone, the stirring of the treatment liquid is stopped (step 92). Thereafter, the treatment is ended (step 93).

According to the second example of the method described above, the mixture containing one or both of halosilanes and hydrolysates of the halosilanes is brought into contact with the treatment liquid having a pH of 8 to 14 and having a mass corresponding to 100 times or more the mass of the mixture. During this treatment, the treatment liquid and the mixture are brought into contact while the treatment liquid is being stirred. This can accelerate the reaction between the mixture and the treatment liquid. Furthermore, during the treatment, the temperature variation of the treatment liquid is maintained at 10° C. or less, and the pH of the treatment liquid is maintained in the range of 8 to 14. By maintaining the temperature variation of the treatment liquid during the treatment at 10° C. or less, the treatment can proceed moderately. Further, by maintaining the pH of the treatment liquid during the treatment in the range of 8 to 14, stagnation or stoppage of the treatment in the middle can be avoided. As a result, the temperature rise can be suppressed while promoting the treatment of the unreacted substance, and thus the rendering-harmless treatment can be safely performed.

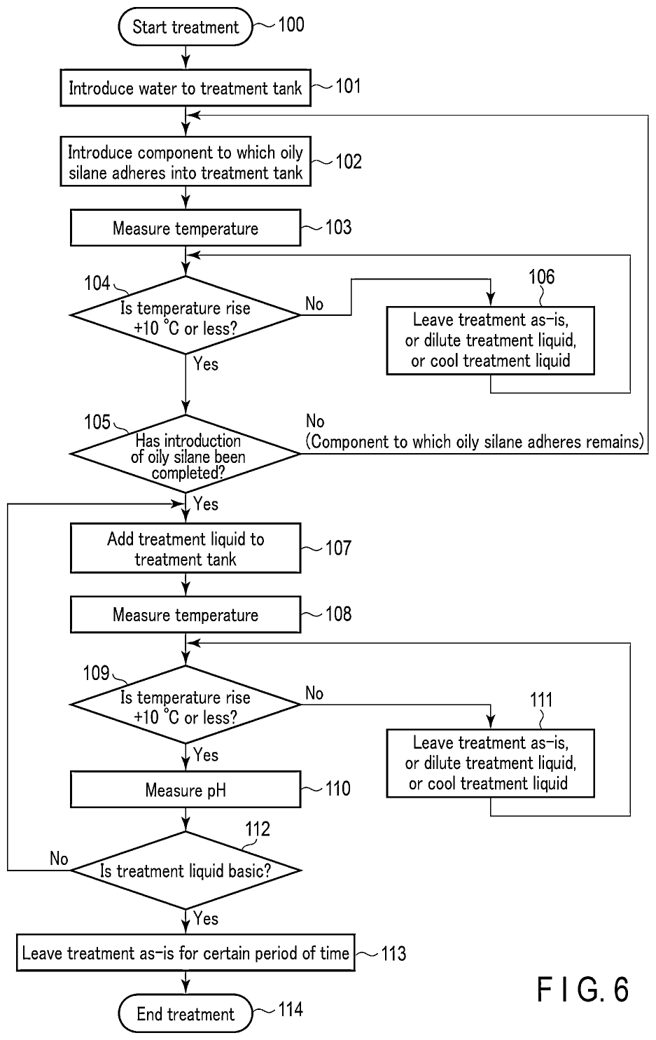

FIG. 6 is a flowchart showing a third example of the treatment method.

After a mixture containing one or both of halosilanes and hydrolysates of the halosilanes is deposited as a byproduct in the discharge path or the like of the epitaxial growth apparatus or the like illustrated in FIG. 1, the treatment is started (step 100). A water solvent (for example, water) is supplied from the water solvent tank 22 to the treatment tank 25 (step 101). Instead of water, an aqueous solution to which an additive such as a surfactant is added may be used. A treatment target member 37 (for example, a component to which oily silane adheres) is introduced into the treatment tank 25 (step 102). Then, the hydrolysis treatment for the byproduct deposited on the treatment target member 37 is started. The temperature of the water solvent in the treatment tank 25 is measured by the temperature sensor 50 (step 103). The control unit 21 compares this measured value with an initially measured value, and compares the temperature variation obtained by this comparison with a reference value (for example, +10° C.) (step 104). If the temperature variation exceeds +10° C. (No in step 104), (A) the treatment liquid is left as-is, (B) the amount of the water solvent is increased by supplying the liquid from the water solvent tank 22 to the treatment tank 25, or (C) the water solvent in the treatment tank 25 is cooled by the cooling unit 51 (step 106). In step 106, only one of the steps (A) to (C) may be performed, or two or more of the steps (A) to (C) may be performed in combination. Step 106 is performed until the temperature variation is reduced to +10° C. or less.

If the temperature variation is +10° C. or less (Yes in step 104), it is checked whether or not there is any untreated treatment target member 37 (for example, a component to which oily silane adheres) that has not been introduced into the treatment tank 25 (step 105). As a result of the check, if there still is an untreated treatment target member 37 (No in step 105), the process starts again from step 102 in which a new treatment target member 37 is introduced into the treatment tank 25. If the hydrolysis treatment for the byproduct has been completed (Yes in step 105), the treatment liquid is supplied from the treatment liquid tank 23 to the treatment tank 25 (step 107). Then, a rendering-harmless treatment for the byproduct deposited on the treatment target member 37 is started. The temperature of the treatment liquid in the treatment tank 25 is measured by the temperature sensor 50 (step 108). The control unit 21 compares this measured value with an initially measured value, and compares the temperature variation obtained by this comparison with a reference value (for example, +10° C.) (step 109). If the temperature variation exceeds +10° C. (No in step 109), (a) the treatment liquid is left as-is, (b) the water solvent is supplied from the water solvent tank 22 to the treatment tank 25 to lower the base concentration of the treatment liquid, or (c) the treatment liquid in the treatment tank 25 is cooled by the cooling unit 51 (step 111). In step 111, only one of the steps (a) to (c) may be performed, or two or more of the steps (a) to (c) may be performed in combination.

If the temperature variation is +10° C. or less (Yes in step 109), the pH of the treatment liquid in the treatment tank 25 is measured by the pH measuring device of the sensor 28 (step 110). If the pH of the treatment liquid is not basic, for example, if the pH is less than 8 (No in step 112), there is a high probability that the rendering-harmless treatment will be stopped in the middle due to the shortage of the basic component. Then, the process returns to step 107, and the treatment liquid is supplied from the treatment liquid tank 23 to the treatment tank 25 to continue the rendering-harmless treatment.

If the pH of the treatment liquid is basic, for example, if the pH is 8 to 14 (Yes in step 112), the treatment target member 37 is left alone for a certain period of time while being immersed in the treatment liquid (step 113). Thereafter, the treatment is ended (step 114).

According to the third example of the method described above, after the hydrolysis treatment for the halosilanes is performed, the mixture containing the obtained hydrolysates of the halosilanes is brought into contact with the treatment liquid having a pH of 8 to 14 and having a mass corresponding to 100 times or more the mass of the mixture. In the hydrolysis treatment and the subsequent rendering-harmless treatment, the temperature variation of the treatment liquid during the treatment is maintained at 10° C. or lower, whereby the hydrolysis treatment and the rendering-harmless treatment can proceed moderately. Furthermore, by maintaining the pH of the treatment liquid during the rendering-harmless treatment in the range of 8 to 14, stagnation or stoppage of the treatment in the middle can be avoided. As a result, the treatment can be smoothly performed while suppressing the temperature rise, and thus the rendering-harmless treatment can be safely performed.

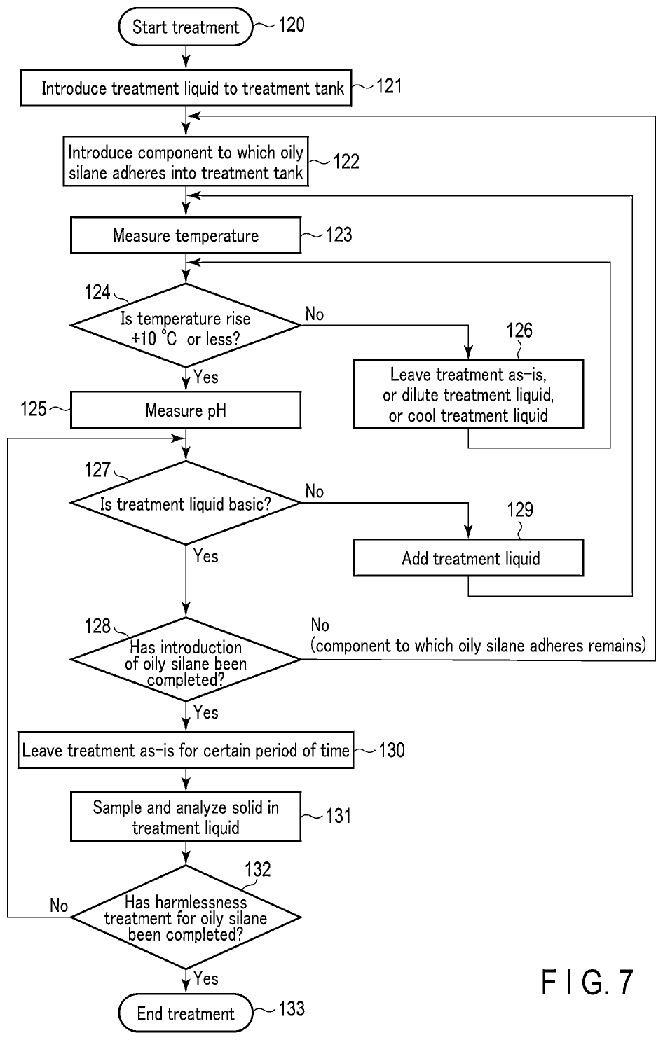

FIG. 7 is a flowchart showing a fourth example of the treatment method.

After a mixture containing one or both of halosilanes and hydrolysates of the halosilanes is deposited as a byproduct in the discharge path or the like of the epitaxial growth apparatus or the like illustrated in FIG. 1, the treatment is started (step 120). A treatment liquid (for example, a chemical liquid) is supplied from the treatment liquid tank 23 to the treatment tank 25 (step 121). A treatment target member 37 (for example, a component to which oily silane adheres) is introduced into the treatment tank 25 (step 122). Then, a rendering-harmless treatment for the byproduct deposited on the treatment target member 37 is started. The temperature of the treatment liquid in the treatment tank 25 is measured by the temperature sensor 50 (step 123). The control unit 21 compares this measured value with an initially measured value, and compares the temperature variation obtained by this comparison with a reference value (for example, +10° C.) (step 124). If the temperature variation exceeds +10° C. (No in step 124), (a) the treatment liquid is left as-is, (b) a water solvent is supplied from the water solvent tank 22 to the treatment tank 25 to lower the base concentration of the treatment liquid, or (c) the treatment liquid in the treatment tank 25 is cooled by the cooling unit 51 (step 126). In step 126, only one of the steps (a) to (c) may be performed, or two or more of the steps (a) to (c) may be performed in combination. Step 126 is performed until the temperature variation is reduced to +10° C. or less.

If the temperature variation is +10° C. or less (Yes in step 124), the pH of the treatment liquid in the treatment tank 25 is measured by the pH measuring device of the sensor 28 (step 125). If the pH of the treatment liquid is not basic, for example, if the pH is less than 8 (No in step 127), there is a high probability that the rendering-harmless treatment will be stopped in the middle due to the shortage of the basic component. In this case, the treatment liquid is supplied from the treatment liquid tank 23 to the treatment tank 25 (step 129). Thereafter, the process returns to the temperature measurement of the treatment liquid (step 123) in order to continue the rendering-harmless treatment.

If the pH of the treatment liquid is basic, for example, if the pH is 8 to 14 (Yes in step 127), it is checked whether or not there is any untreated treatment target member 37 (for example, a component to which oily silane adheres) that has not been introduced into the treatment tank 25 (step 128). As a result of the check, if there still is an untreated treatment target member 37 (No in step 128), the process starts again from step 122 in which a new treatment target member 37 is introduced into the treatment tank 25. If the rendering-harmless treatment for the byproduct has been completed (Yes in step 128), the treatment target member 37 is left alone for a certain period of time while being immersed in the treatment liquid (step 130). The left-alone time can be, for example, 1 hour or longer, and more preferably 10 hours or longer. After being left alone, a part of the solid immersed in the treatment liquid in the treatment tank 25 is sampled, and the chemical structural formula or the bonding state of atoms of the solid is confirmed by any one of Raman spectroscopy, infrared spectroscopy, and nuclear magnetic resonance spectroscopy (step 131). If the halosilanes and the hydrolysates of the halosilanes are contained in the solid (No in step 132), the process returns to the step of maintaining the basicity of the treatment liquid (step 127), and the rendering-harmless treatment is continued. If the halosilanes and the hydrolysates of the halosilanes cannot be detected (Yes in step 132), the treatment is ended (step 133).

According to the fourth example of the method described above, a spectral intensity of any one of the Raman spectrum, the IR spectrum, and the NMR spectrum is measured for the target treated by the method of the first example, and thus the progress of the rendering-harmless treatment can be appropriately determined

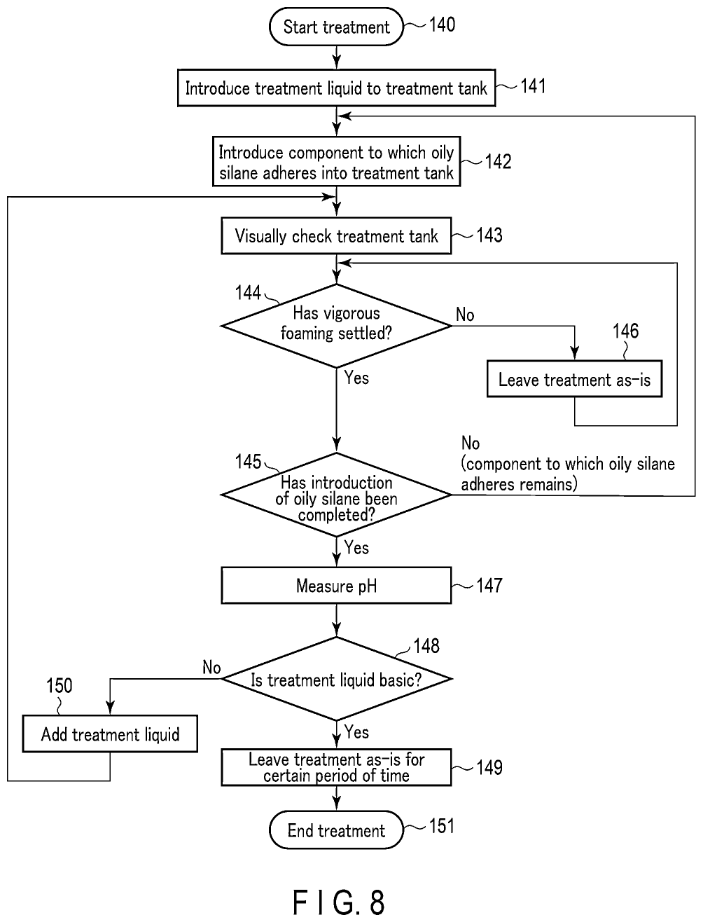

FIG. 8 is a flowchart showing a fifth example of the treatment method.

After a mixture containing one or both of halosilanes and hydrolysates of the halosilanes is deposited as a byproduct in the discharge path or the like of the epitaxial growth apparatus or the like illustrated in FIG. 1, the treatment is started (step 140). A treatment liquid (for example, a chemical liquid) is supplied from the treatment liquid tank 23 to the treatment tank 25 (step 141). A treatment target member 37 (for example, a component to which oily silane adheres) is introduced into the treatment tank 25 (step 142). Then, a rendering-harmless treatment for the byproduct deposited on the treatment target member 37 is started. The state in the treatment tank 25 is visually checked (step 143). If vigorous foaming in the treatment tank 25 is observed (No in step 144), the treatment tank 25 is left alone until the foaming settles (step 146). If the vigorous foaming has settled (Yes in step 144), it is checked whether or not there is any untreated treatment target member 37 (for example, a component to which oily silane has adhered) that has not been introduced into the treatment tank 25 (step 145). As a result of the check, if there still is an untreated treatment target member 37 (No in step 145), the process starts again from step 142 in which a new treatment target member 37 is introduced into the treatment tank 25. If the rendering-harmless treatment for the byproduct has been completed (Yes in step 145), the pH of the treatment liquid in the treatment tank 25 is measured by the pH measuring device of the sensor 28 (step 147). If the pH of the treatment liquid is not basic, for example, if the pH is less than 8 (No in step 148), there is a high probability that the rendering-harmless treatment will be stopped in the middle due to the shortage of the basic component. In this case, the treatment liquid is supplied from the treatment liquid tank 23 to the treatment tank 25 (step 150). Thereafter, the process returns to the visual check of the state in the treatment tank 25 (step 143) in order to continue the rendering-harmless treatment.

If the pH of the treatment liquid is basic, for example, if the pH is 8 to 14 (Yes in step 148), the treatment target member 37 is left alone for a certain period of time while being immersed in the treatment liquid (step 149). After being left alone, the treatment is ended (step 151).

According to the fifth example of the method described above, the mixture containing one or both of halosilanes and hydrolysates of the halosilanes is brought into contact with the treatment liquid having a pH of 8 to 14 and having a mass corresponding to 100 times or more the mass of the mixture. During this treatment, the foaming state of the treatment liquid is checked. The larger the amount of heat generation by the reaction, the more vigorous the foaming of the treatment liquid. Therefore, it is possible to estimate the temperature rise of the treatment liquid by a simple method of visually checking the foaming state of the treatment liquid. Further, by maintaining the pH of the treatment liquid during the treatment in the range of 8 to 14, stagnation or stoppage of the treatment in the middle can be avoided. As a result, the treatment can be smoothly performed while suppressing the temperature rise by a simple method, and thus the rendering-harmless treatment can be performed by a safe and simple method.

### WORKING EXAMPLES

Working examples will be described below.

### Working Example 1

First, a material gas was introduced into an epitaxial growth apparatus and reacted with a silicon substrate at a temperature of 800° C. to form a monocrystalline silicon film on the silicon substrate. As the material gas, a mixed gas having hydrogen gas mixed with dichlorosilane and hydrogen chloride was used. The concentration of hydrogen in the mixed gas was 95 vol % or more.

Next, the pipe of the epitaxial growth apparatus was disassembled under nitrogen atmosphere to collect oily silane as a byproduct. The byproduct was a white creamy liquid. Subsequently, the collected byproduct was analyzed by the method described above, and confirmed to include chlorosilanes having a cyclic structure considered to correspond to any one of the structural formulae (a) to (d), (1-1), (2-1), (12-1), and (14-1).

Next, 0.05 g of the byproduct was weighed out and put into a petri dish in an argon-purged glove box. Subsequently, the petri dish was placed in an airtight container and moved to a fume hood under air atmosphere. The temperature in the fume hood was 26.4° C. and the humidity was 55%.

Next, a treatment liquid was prepared. As the treatment liquid, a solution obtained by dissolving tetramethylammonium hydroxide (TMAH) in water was used. The concentration of TMAH in the treatment liquid was 2.5 mass %.

Next, the petri dish was removed from the airtight container, and 5 g of the treatment liquid was added to have the byproduct react with the treatment liquid. As a result, fine foaming from the byproduct was observed. This treatment was performed while measuring the temperature of the treatment liquid using a thermometer. The mass ratio of the treatment liquid to the byproduct was 100.

### Working Examples 2-4, 6, 8-11, and 13

The treatment was performed in the same manner as in Working Example 1 except that the kind of base, the base concentration, the pH, the mass of the added treatment liquid, and the ratio of the mass of the added treatment liquid to the mass of the byproduct in the treatment liquid were changed as shown in Table 1 below.

### Working Example 5

First, in the same manner as described in Working Example 1, 0.05 g of the byproduct was weighed and put into a petri dish. Then, 5 g of water was dropped into the petri dish and the petri dish was left alone for 1 hour. Then, 5 g of the treatment liquid was dropped into the petri dish. The byproduct was treated in this manner. The temperature of the treatment liquid was measured in the same manner as in Working Example 1. The mass ratio of the treatment liquid to the byproduct was 100.

As the treatment liquid, a solution obtained by dissolving tetramethylammonium hydroxide (TMAH) in water was used. The concentration of TMAH in the treatment liquid was 2.5 mass %.

### Working Examples 7 and 12

The treatment was performed in the same manner as in Working Example 5 except that the kind of base, the concentration of base, and the pH of the treatment liquid were changed as shown in Table 1 below.

### Comparative Examples 1-3 and 5-7

The treatment was performed in the same manner as in Working Example 1 except that the kind of base, the base concentration, the pH, the mass of the added treatment liquid, and the ratio of the mass of the added treatment liquid to the mass of the byproduct in the treatment liquid were changed as shown in Table 2 below.

### Comparative Example 4

The treatment was performed in the same manner as in Working Example 5 except that the mass of added water in the hydrolysis reaction, the base concentration of the treatment liquid, the mass of the added treatment liquid, and the ratio of the mass of the added treatment liquid to the mass of the byproducts were changed as shown in Table 2 below.

### (pH Measurement)

The pH of the treatment liquid before and after the treatment of the byproduct was measured using a pH test paper. The results are shown in Tables 1 to 4.

### (Temperature Measurement)

The temperature of the treatment liquid under treatment was continuously measured by a thermometer and recorded. The maximum temperature (° C.) and the maximum temperature change (° C.), which is the difference between the temperature of the treatment liquid before the start of treatment and the maximum temperature, are indicated in Tables 3 and 4.

### (Friction Sensitivity Test and Flame Sensitivity Test)

Whether or not the treatment liquid after the treatment of the byproduct includes a flammable solid was checked by the following method.

### Friction Sensitivity Test

First, the treatment liquid on the petri dish was sufficiently dried in an exhaust booth. Next, small amounts of solid matter remaining on the petri dish were sampled into containers made of resin and SUS, respectively. Next, friction sensitivity tests were performed using resin and metal, respectively. In the friction sensitivity test using resin, a spatula made of fluorine resin was pressed against the solid matter on a container made of fluorine resin and the spatula was moved on the petri dish. At this time, whether the solid matter was ignited or not was visually checked. The results of the friction sensitivity test (resin) are shown in Tables 3 and 4, with “yes” indicating that ignition occurred and “no” indicating no ignition occurred. On the other hand, in the friction sensitivity test using metal, a spatula made of SUS was pressed against the solid matter on a container made of SUS and the spatula was moved on the petri dish. At this time, whether the solid matter was ignited or not was visually checked. The results of the friction sensitivity test (metal) are shown in Tables 3 and 4, with “yes” indicating that ignition occurred and “no” indicating that no ignition occurred.

### Flame Sensitivity Test

The solid matter sampled in the container made of SUS was brought into contact with a flame by using a portable ignition device, and whether or not ignition occurred was visually checked. Gas used in the portable ignition device was butane gas. The temperature of the flame was about 500° C. The results of the flame sensitivity tests are shown in Tables 3 and 4, with “yes” indicating that the solid matter ignited, and “no” indicating that the solid matter did not ignite.

TABLE 1

| | Oily silane | Treatment liquid | | | | | Hydrolysate |
|---|---|---|---|---|---|---|---|
| | Amount of | | | | Added | Ratio of | Amount of |
| | sample | Kind of | Concentration | | amount | added | added water |
| | (g) | base | (mass %) | pH | (g) | amount | (g) |
| Working | 0.05 | TMAH | 2.5 | 14 | 5 | 100 | no |
| ex. 1 | | | | | | times | |
| Working | 0.05 | TMAH | 0.26 | 12.5 | 50 | 1000 | no |
| ex. 2 | | | | | | times | |
| Working | 0.05 | TMAH | 0.026 | 11 | 500 | 10000 | no |
| ex. 3 | | | | | | times | |
| Working | 0.05 | TMAH | 1 | 13 | 20 | 400 | no |
| ex. 4 | | | | | | times | |
| Working | 0.05 | TMAH | 2.5 | 14 | 5 | 100 | 5 |
| ex. 5 | | | | | | times | |
| Working | 0.05 | Choline | 4 | 14 | 5 | 100 | no |
| ex. 6 | | hydroxide | | | | times | |
| Working | 0.05 | Choline | 4 | 14 | 5 | 100 | 5 |
| ex. 7 | | hydroxide | | | | times | |
| Working | 0.05 | C₆H₅ONa | 1 | 11 | 50 | 1000 | no |
| ex. 8 | | | | | | times | |
| Working | 0.05 | NaOH | 10 | 14 | 5 | 100 | no |
| ex. 9 | | | | | | times | |
| Working | 0.05 | Ca(OH)₂ | 10 | 14 | 5 | 100 | no |
| ex. 10 | | | | | | times | |
| Working | 0.05 | NaHCO₃ | 10 | 8 | 5 | 100 | no |
| ex. 11 | | | | | | times | |
| Working | 0.05 | NaHCO₃ | 10 | 8 | 5 | 100 | 5 |
| ex. 12 | | | | | | times | |
| Working | 0.02 | Choline | 0.26 | 10 | 20 | 1000 | no |
| ex. 13 | | hydroxide | | | | times | |

TABLE 2

| | Oily silane | Treatment liquid | | | | | Hydrolysate |
|---|---|---|---|---|---|---|---|
| | Amount of | | | | Added | Ratio of | Amount of |
| | sample | Kind of | Concentration | | amount | added | added water |
| | (g) | base | (mass %) | pH | (g) | amount | (g) |
| Compar. | 0.05 | TMAH | 5 | 14 | 2.5 | 50 times | no |
| ex. 1 | | | | | | | |
| Compar. | 0.05 | TMAH | 25 | 14 | 0.5 | 10 times | no |
| ex. 2 | | | | | | | |
| Compar. | 0.05 | TMAH | 25 | 14 | 2 | 40 times | no |
| ex. 3 | | | | | | | |
| Compar. | 0.05 | TMAH | 25 | 14 | 0.5 | 10 times | 1 |
| ex. 4 | | | | | | | |
| Compar. | 0.05 | NaOH | 10 | 14 | 1 | 20 times | no |
| ex. 5 | | | | | | | |
| Compar. | 0.05 | NaHCO₃ | 10 | 8 | 1 | 20 times | no |
| ex. 6 | | | | | | | |
| Compar. | 0.05 | NaHCO₃ | 2 | 8 | 1 | 20 times | no |
| ex. 7 | | | | | | | |

TABLE 3

| | During | | | | | |
|---|---|---|---|---|---|---|
| | treat- | After | | | | |
| | ment | treat- | | | | |
| | Maximum | ment | | Result of ignition evaluation | | |
| | temper- | Maximum | After | Friction | Friction | Flame |
| | ature | temper- | treat- | sensi- | sensi- | sensi- |
| | change | ature | ment | tivity | tivity | tivity |
| | (° C.) | (° C.) | pH | (resin) | (metal) | test |
| Working | 2.2 | 20 | >11 | no | no | no |
| ex. 1 | | | | | | |
| Working | 0 | 17.8 | >11 | no | no | no |
| ex. 2 | | | | | | |
| Working | 0 | 17.8 | >11 | no | no | no |
| ex. 3 | | | | | | |
| Working | 0.7 | 18.5 | >11 | no | no | no |
| ex. 4 | | | | | | |
| Working | 1.2 | 19.0 | >11 | no | no | no |
| ex. 5 | | | | | | |
| Working | 4.5 | 22.3 | >11 | no | no | no |
| ex. 6 | | | | | | |
| Working | 3.0 | 20.8 | >11 | no | no | no |
| ex. 7 | | | | | | |
| Working | 0 | 17.8 | >11 | no | no | no |
| ex. 8 | | | | | | |
| Working | 4.7 | 22.5 | >11 | no | no | no |
| ex. 9 | | | | | | |
| Working | 3.5 | 21.3 | >11 | no | no | no |
| ex. 10 | | | | | | |
| Working | 2.7 | 20.5 | 8 | no | no | no |
| ex. 11 | | | | | | |
| Working | 1.2 | 19.0 | 8 | no | no | no |
| ex. 12 | | | | | | |
| Working | 0 | 17.8 | >11 | no | no | no |
| ex. 13 | | | | | | |

TABLE 4

| | During | | | | | |
|---|---|---|---|---|---|---|
| | treat- | After | | | | |
| | ment | treat- | | | | |
| | Maximum | ment | | Result of ignition evaluation | | |
| | temper- | Maximum | After | Friction | Friction | Flame |
| | ature | temper- | treat- | sensi- | sensi- | sensi- |
| | change | ature | ment | tivity | tivity | tivity |
| | (° C.) | (° C.) | pH | (resin) | (metal) | test |
| Compar. | 8.0 | 25.8 | >11 | no | no | no |
| ex. 1 | | | | | | |
| Compar. | 45.2 | 63.0 | >11 | no | no | yes |
| ex. 2 | | | | | | |
| Compar. | 15.2 | 33.0 | >11 | no | no | no |
| ex. 3 | | | | | | |
| Compar. | 5.5 | 23.3 | >11 | no | no | no |
| ex. 4 | | | | | | |
| Compar. | 35.2 | 53.0 | >11 | no | no | no |
| ex. 5 | | | | | | |
| Compar. | 15.0 | 32.8 | >11 | no | no | no |
| ex. 6 | | | | | | |
| Compar. | 7.2 | 25.0 | 1 | no | no | yes |
| ex. 7 | | | | | | |

As is clear from Tables 1 to 4, according to Working Examples 1 to 13 of the treatment method, the temperature variation of the treatment liquid during the treatment was within a range of 10° C. or less, and as a result, the maximum temperature was lower than those in Comparative Examples 1 to 7. The pH of the treatment liquid after the treatment was 8 or more; that is, the treatment liquid was basic. Further, according to Working Examples 1 to 13 of the treatment method, ignition did not occur in either the friction sensitivity test or the fire sensitivity test, and no explosive substances were present in the treatment liquid after the treatment of the byproducts.

In contrast, as in Comparative Examples 1 to 7, in a case where the ratio of the mass of the treatment liquid to the mass of the byproduct was less than 100 even if the treatment liquid was basic, the maximum temperature during the treatment was higher than that in the Working Examples. Further, in a case where the maximum temperature during the treatment was extremely high as in Comparative Example 2, or where the pH of the treatment liquid after the treatment was acidic as in Comparative Example 7, ignition occurred in the sensitivity test. The results indicate that the safety of the treatment can be enhanced by suppressing the temperature rise during the treatment or by keeping the treatment liquid basic.

As shown in Working Examples 2, 3, 4, 8, and 13, in a case where the ratio of the mass of the added treatment liquid to the mass of the target of treatment exceeds 100, almost no temperature rise occurs during the treatment, and the safety is enhanced.

Comparison between Working Example 1 and Example 5 shows that the maximum temperature is lower and the temperature rise is smaller during the treatment in the method of Working Example 5, in which the rendering-harmless treatment is performed after the hydrolysis of halosilanes. The same tendency can be seen from the comparison between Working Examples 6 and 7 and the comparison between Working Examples 11 and 12.

When Working Examples 9 and 10, among the examples using a base having a base dissociation constant Kb of more than 1, are compared, it is found that the maximum temperature of Working Example 9 is higher. The reason for this result will be described. The magnitude of the temperature rise may be affected by the amount of heat generated by the reaction, the reaction rate, the heat radiation rate, the heat capacity, and the like. The amount of generated heat and the heat capacity are considered to be substantially the same between Working Examples 9 and 10. Since NaOH of Working Example 9 has a smaller molecular weight than Ca(OH)₂ of Working Example 10, the molar concentration of the treatment liquid of Working Example 9 is higher than that of Working Example 10 if the base concentrations of the aqueous solutions of both working examples are 10 mass %. As a result, it is presumed that the hydroxide ion concentration in the treatment liquid was higher in Working Example 9, and therefore the reaction rate of the treatment was higher, the temperature rise range was larger, and the maximum temperature was higher.

In the above working examples, the temperature variation of the treatment liquid during the treatment was maintained at 10° C. or less without diluting the treatment liquid or cooling the treatment liquid. As described above, the magnitude of the temperature rise may be affected by the amount of heat generated by the reaction, the reaction rate, the heat radiation rate, the heat capacity, and the like. Therefore, in a case where the amount of generated heat increases due to an increase in the mass of the treatment target, for example, the temperature rise during the treatment can be reliably suppressed by combining the aforementioned working examples with the first to fifth examples of the treatment method of the embodiment, and thus the rendering-harmless treatment can be performed more safely.

According to at least one embodiment or working example described above, the mixture containing one or both of halosilanes and hydrolysates of the halosilanes is brought into contact with the treatment liquid having a pH of 8 to 14 and having a mass corresponding to 100 times or more the mass of the mixture. This makes it possible to safely perform rendering-harmless treatment on the halosilanes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The following are supplementary notes for the invention recited in the claims of the present application originally filed.
<1> A treatment method for treating a mixture containing one or both of halosilanes and hydrolysates of the halosilanes, the method comprising:
bringing the mixture into contact with a treatment liquid having a pH of 8 to 14 and having a mass corresponding to 100 times or more a mass of the mixture.
<2> The treatment method according to <1>, further comprising setting a temperature variation of the treatment liquid during treatment to 10° C. or less.
<3> The treatment method according to <1> or <2>, further comprising adjusting the pH of the treatment liquid during treatment to a range of 8 to 14.
<4> The treatment method according to any one of <1> to <3>, wherein the bringing the mixture into contact with the treatment liquid is performed while the treatment liquid is being stirred.
<5> The treatment method according to any one of <1> to <4>, wherein the bringing the mixture into contact with the treatment liquid is performed by introducing the mixture into the treatment liquid.
<6> The treatment method according to any one of <1> to <5>, wherein the treatment liquid is an aqueous solution containing at least one of an organic base or an inorganic base.
<7> The method according to <6>, wherein the treatment liquid comprises at least one of tetramethylammonium hydroxide or choline hydroxide.
<8> The treatment method according to item <6>, wherein the treatment liquid comprises sodium hydrogen carbonate.

What is claimed is:

1. A treatment method for treating a mixture containing one or both of halosilanes and hydrolysates of the halosilanes, the method comprising:
bringing the mixture into contact with a treatment liquid having a pH of 8 to 14 and having a mass corresponding to 100 times or more a mass of the mixture.

2. The treatment method according to claim 1, further comprising setting a temperature variation of the treatment liquid during treatment to 10° C. or less.

3. The treatment method according to claim 2, wherein the setting the temperature variation is performed by at least one of (a) the treatment liquid is left as-is, (b) the treatment liquid is diluted, or (c) the treatment liquid is cooled when the temperature variation exceeds a reference value.

4. The treatment method according to claim 1, further comprising adjusting the pH of the treatment liquid during treatment to a range of 8 to 14.

5. The treatment method according to claim 1, wherein the bringing the mixture into contact with the treatment liquid is performed while the treatment liquid is being stirred.

6. The treatment method according to claim 1, wherein the bringing the mixture into contact with the treatment liquid is performed by introducing the mixture into the treatment liquid.

7. The treatment method according to claim 1, wherein the treatment liquid is an aqueous solution containing at least one of an organic base or an inorganic base.

8. The treatment method according to claim 7, wherein the treatment liquid comprises at least one of tetramethylammonium hydroxide or choline hydroxide.

9. The treatment method according to claim 7, wherein the treatment liquid comprises sodium hydrogen carbonate.
